(19) United States
(12) Patent Application Publication
(10) Pub. No.: US 2025/0176201 A1
(43) Pub. Date: May 29, 2025

(54) SEMICONDUCTOR PROCESSING INTEGRATION FOR BIPOLAR JUNCTION TRANSISTOR (BJT)

(71) Applicant: TEXAS INSTRUMENTS INCORPORATED, Dallas, TX (US)

(72) Inventors: Hiroshi Yasuda, Plano, TX (US); Jonathan Lane, Sandy, UT (US); Giulio Albini, Draper, UT (US); Michael Todd, Lehi, UT (US); Robert Cassel, Lehi, UT (US)

(21) Appl. No.: 18/520,527

(22) Filed: Nov. 27, 2023

(51) Int. Cl. H01L 29/737; H01L 27/06; H01L 29/08; H01L 29/66

(52) U.S. Cl. CPC H10D 10/821; H10D 10/021; H10D 62/137; H10D 84/401

(57) ABSTRACT

The present disclosure generally relates to semiconductor processing integration for a bipolar junction transistor (BJT). In an example, a semiconductor device includes a semiconductor substrate, a pedestal dielectric layer, a collector layer, a base layer, and an emitter layer. The semiconductor substrate includes a bipolar junction transistor region. The pedestal dielectric layer is in the bipolar junction transistor region and is over an upper surface of the semiconductor substrate. The collector layer is on the upper surface of the semiconductor substrate and is through the pedestal dielectric layer. The base layer is on the collector layer and an upper surface of the pedestal dielectric layer. The pedestal dielectric layer extends laterally over the upper surface of the semiconductor substrate from the base layer. The emitter layer is on the base layer.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices. Further, integrating a BJT with other devices may complicate that semiconductor processing.

### SUMMARY

An example described herein is a semiconductor device. The semiconductor device includes a semiconductor substrate, a pedestal dielectric layer, a collector layer, a base layer, and an emitter layer. The semiconductor substrate includes a bipolar junction transistor region. The pedestal dielectric layer is in the bipolar junction transistor region and is over an upper surface of the semiconductor substrate. The collector layer is on the upper surface of the semiconductor substrate and is through the pedestal dielectric layer. The base layer is on the collector layer and an upper surface of the pedestal dielectric layer. The pedestal dielectric layer extends laterally over the upper surface of the semiconductor substrate from the base layer. The emitter layer is on the base layer.

Another example is a method. A gate layer is formed over a semiconductor substrate. An opening is formed through the gate layer in a bipolar junction transistor (BJT) region. A collector layer is formed in the opening and on an upper surface of the semiconductor substrate. A base layer is formed on the collector layer. An emitter layer is formed on the base layer. The gate layer is patterned, after forming the emitter layer, into a gate electrode of a transistor in a complementary field effect transistor (CFET) region of the semiconductor substrate.

A further example is a method. A pedestal dielectric layer is formed over a semiconductor substrate in a bipolar junction transistor region. A gate layer is formed over the semiconductor substrate and over the pedestal dielectric layer. A first opening is formed through the gate layer to the pedestal dielectric layer. Sidewalls of the gate layer defining the first opening are over the pedestal dielectric layer. A second opening is formed, through the first opening, through the pedestal dielectric layer to an upper surface of the semiconductor substrate. A collector layer is formed, through the first opening, in the second opening and on the upper surface of the semiconductor substrate. A base layer is formed, through the first opening, on the collector layer. An emitter layer is formed, through the first opening, on the base layer. The gate layer is patterned into a first gate electrode of a p-type transistor and into a second gate electrode of an n-type transistor. The p-type transistor and the n-type transistor are in a complementary field effect transistor (CFET) region of the semiconductor substrate.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 36 are respective cross-sectional views of a semiconductor device in intermediate stages of manufacturing according to some examples.

FIGS. 37 through 43 are respective cross-sectional views of a semiconductor device in intermediate stages of manufacturing according to some examples.

FIG. 44 is a layout view of the bipolar junction transistor (BJT) of the semiconductor device of FIGS. 36 and 43 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing integration for a bipolar junction transistor (BJT). Some examples include a semiconductor device including a BJT. A semiconductor substrate includes a BJT region. A pedestal dielectric layer is in the BJT region and over an upper surface of the semiconductor substrate. A collector layer is on the upper surface of the semiconductor substrate and through the pedestal layer. A base layer is on the collector layer and an upper surface of the pedestal dielectric layer. The pedestal dielectric layer extends laterally over the upper surface of the semiconductor substrate from the base layer. An emitter layer is on the base layer. Semiconductor processing to form such a BJT may enable vertical and horizontal scaling of the BJT, which may improve characteristics (e.g., parasitic resistances and capacitances) of the BJT. Other benefits and advantages may be achieved.

Various examples are described subsequently. Although the specific examples may illustrate various aspects of the above generally described features, examples may incorporate any combination of the above generally described features (which are described in more detail in examples below).

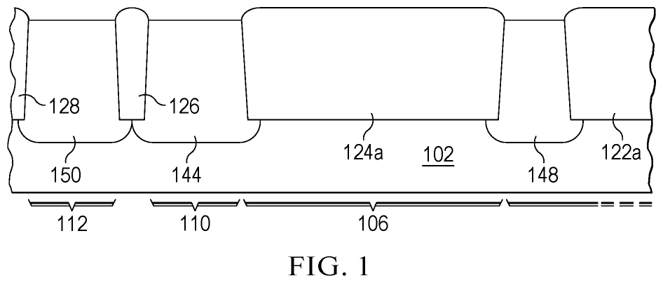

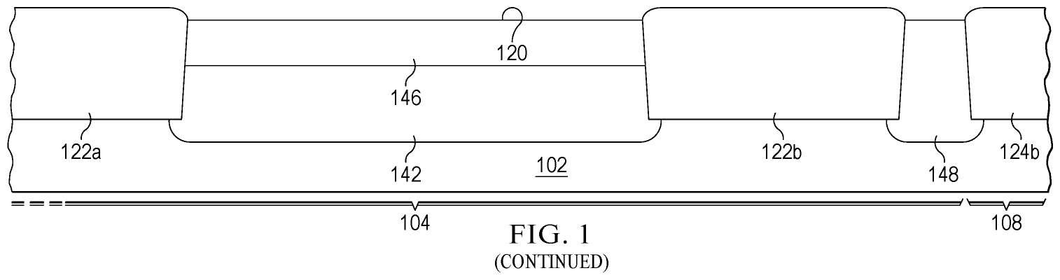

FIGS. 1 through 36 are respective cross-sectional views of a semiconductor device in intermediate stages of manufacturing according to some examples. Referring to FIG. 1, a semiconductor substrate 102 is provided. The semiconductor substrate 102 includes a BJT region 104, a first transition region 106, a second transition region 108, a p-type field effect transistor (pFET) region 110, and an n-type field effect transistor (nFET) region 112. Together, the pFET region 110 and the nFET region 112 are included in a complementary field effect transistor (CFET) region.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as the BJT, pFET, and nFET (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 120 in and/or on which devices (e.g., the BJT, pFET, and nFET) are formed. In the illustrated example, the semiconductor material of the semiconductor substrate 102 is p-doped with a p-type dopant. In some examples, the semiconductor substrate 102 is p-doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 122 (including a first portion 122a and a second portion 122b), 124 (including a first portion 124a and a second portion 124b), 126, 128 are formed on the semiconductor substrate 102. In the illustrated example, the isolation structures 122, 124, 126, 128 are shallow trench isolation structures (STIs) extending from the upper surface 120 of the semiconductor substrate 102 into the semiconductor substrate 102. As illustrated, the isolation structures 122-128 are also raised above the upper surface 120 of the semiconductor substrate 102, and in other examples, the isolation structures 122-128 may have respective upper surfaces co-planar with and/or below the upper surface 120 of the semiconductor substrate 102. The isolation structures 122-128 may include, for example, a liner layer, such as including silicon oxide or silicon nitride, conformally along surfaces of a respective trench in the semiconductor substrate 102 and a fill isolation material, such as silicon oxide, over and on the liner layer.

The isolation structures 122-128, as illustrated, may be formed by depositing a hardmask layer over the semiconductor substrate 102. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 102 using the patterned hardmask layer as a mask. The liner layer may then be conformally deposited in the recesses or trenches and over the patterned hardmask layer (or formed on exposed surfaces of the recesses or trenches—e.g., by an oxidation process), such as by plasma enhanced CVD (PECVD), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 122-128 may be field oxide structures, such as local oxidation of silicon (LOCOS) structures, at the upper surface 120 of the semiconductor substrate 102, which may be formed using a LOCOS process.

The isolation structure 122 laterally defines an active area of the upper surface 120 of the semiconductor substrate 102 on which the BJT is to be formed. The isolation structure 122 laterally encircles the active area of the upper surface 120 of the semiconductor substrate 102 on which the BJT is to be formed. As indicated subsequently, an active portion (e.g., a base layer) of the BJT extends laterally beyond the active area of the upper surface 120 of the semiconductor substrate 102 on which the BJT is formed and over the first portion 122a of the isolation structure 122. Further, the isolation structure 124 defines lateral boundaries of the BJT region 104. The isolation structure 124 laterally encircles the isolation structure 122 with a doped isolation well therebetween, as described subsequently.

The isolation structure 126 and the first portion 124a of the isolation structure 124 laterally define, at least in part, an active area of the upper surface 120 of the semiconductor substrate 102 on which the pFET is to be formed. The active area of the upper surface 120 of the semiconductor substrate 102 on which the pFET is formed defines the lateral boundary of the pFET region 110. Similarly, the isolation structures 126, 128 laterally define, at least in part, an active area of the upper surface 120 of the semiconductor substrate 102 on which the nFET is to be formed. The active area of the upper surface 120 of the semiconductor substrate 102 on which the nFET is formed defines the lateral boundary of the nFET region 112. The CFET region includes the pFET region 110 and the nFET region 112. The laterally exterior boundaries of the pFET region 110 and/or nFET region 112 (or other pFET and/or nFET regions) define the lateral boundary of the CFET region.

The first transition region 106 is defined from a lateral boundary of the BJT region 104 to a nearest lateral boundary of the CFET region (which in the illustrated example is a boundary of the pFET region 110). The first transition region 106 includes the first portion 124a of the isolation structure 124. The second transition region 108 is defined from a lateral boundary of the BJT region 104 to a nearest lateral boundary of another region (not illustrated). The second transition region 108 includes the second portion 124b of the isolation structure 124.

N-type doped wells 142, 144 are formed in the semiconductor substrate 102. The n-type doped wells 142, 144 may be formed by masking (e.g., by a photoresist using photolithography) areas of the semiconductor substrate 102 where an n-type doped well is not to be formed and implanting n-type dopants into the semiconductor substrate 102. The n-type doped well 142 extends from the upper surface 120 of the semiconductor substrate 102 into a depth in the semiconductor substrate 102 and is in the BJT region 104 laterally between the portions 122a, 122b of the isolation structure 122. The n-type doped well 144 extends from the upper surface 120 of the semiconductor substrate 102 into a depth in the semiconductor substrate 102 and is in the pFET region 110 laterally between the first portion 124a of the isolation structure 124 and the isolation structure 126. A concentration of the n-type dopant of the n-type doped wells 142, 144 is greater than a concentration of the p-type dopant of the p-type doped semiconductor substrate 102. In some examples, the n-type doped wells 142, 144 are doped with an n-type dopant (e.g., phosphorus (P) or arsenic (As)) with a concentration in a range from 1×10¹⁵ cm⁻³ to 1×10¹⁷ cm⁻³. Another dopant type and/or other doping concentrations may be implemented.

An n-type doped sub-collector diffusion region 146 is formed in the semiconductor substrate 102 in the n-type doped well 142. The n-type doped sub-collector diffusion region 146 may be formed by masking (e.g., by a photoresist using photolithography) areas of the semiconductor substrate 102 where an n-type doped sub-collector diffusion region is not to be formed and implanting n-type dopants into the semiconductor substrate 102. The n-type doped sub-collector diffusion region 146 extends from the upper surface 120 of the semiconductor substrate 102 into a depth in the n-type doped well 142 in the semiconductor substrate 102 and is in the BJT region 104 laterally between the portions 122a, 122b of the isolation structure 122. A concentration of the n-type doped sub-collector diffusion region 146 is greater than a concentration of the n-type dopant of the n-type dopant of the n-type doped well 142. In some examples, the n-type doped sub-collector diffusion region 146 is doped with an n-type dopant with a concentration in a range from 1×10¹⁸ cm⁻³ to 1×10²⁰ cm⁻³. Another dopant type and/or other doping concentrations may be implemented.

P-type doped wells 148, 150 are formed in the semiconductor substrate 102. The p-type doped wells 148, 150 may be formed by masking (e.g., by a photoresist using photolithography) areas of the semiconductor substrate 102 where a p-type doped well is not to be formed and implanting p-type dopants into the semiconductor substrate 102. The p-type doped well 148 extends from the upper surface 120 of the semiconductor substrate 102 into a depth in the semiconductor substrate 102 and is in the BJT region 104 laterally between the isolation structures 122, 124. The p-type doped well 148 is an isolation ring encircling the active area in which the BJT is to be formed. The p-type doped well 150 extends from the upper surface 120 of the semiconductor substrate 102 into a depth in the semiconductor substrate 102 and is in the nFET region 112 laterally between the isolation structures 126, 128. A concentration of the p-type dopant of the p-type doped wells 148, 150 is greater than a concentration of the p-type dopant of the p-type doped semiconductor substrate 102. In some examples, the p-type doped wells 148, 150 are doped with a p-type dopant (e.g., boron (B)) with a concentration in a range from 1×10¹⁵ cm⁻³ to 1×10¹⁷ cm⁻³. Another dopant type and/or other doping concentrations may be implemented.

Although the semiconductor substrate 102, n-type doped wells 142, 144, n-type doped sub-collector diffusion region 146, and p-type doped wells 148, 150 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

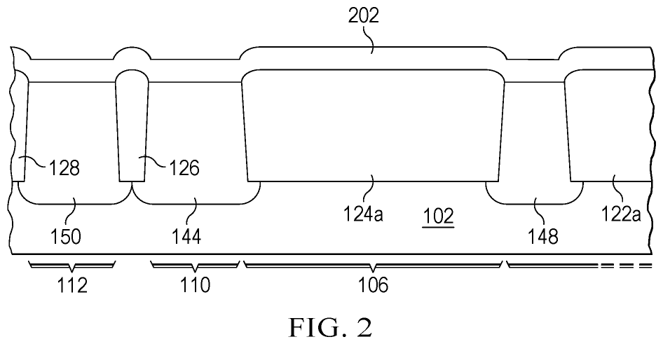

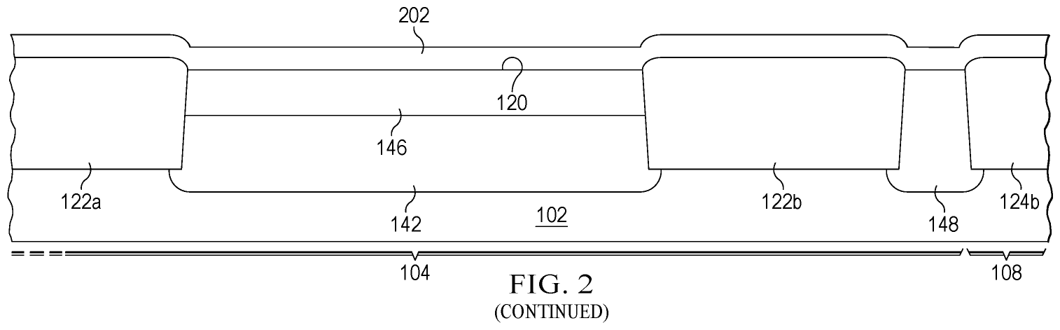

Referring to FIG. 2, a pedestal dielectric layer 202 is formed over the semiconductor substrate 102. The pedestal dielectric layer 202 is conformally deposited over the upper surface 120 of the semiconductor substrate 102 and the isolation structures 122-128. In some examples, the pedestal dielectric layer 202 is silicon oxide (e.g., a tetraethyl orthosilicate (TEOS) oxide) deposited by CVD, although other dielectric materials and/or other deposition processes may be used in other examples.

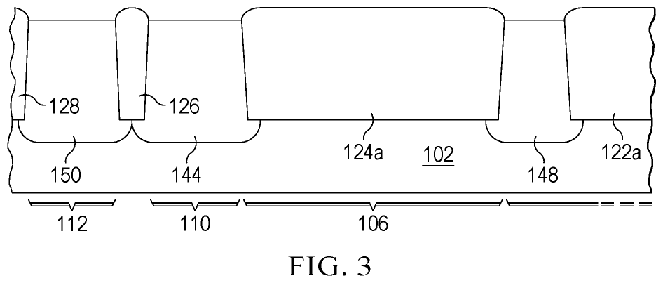

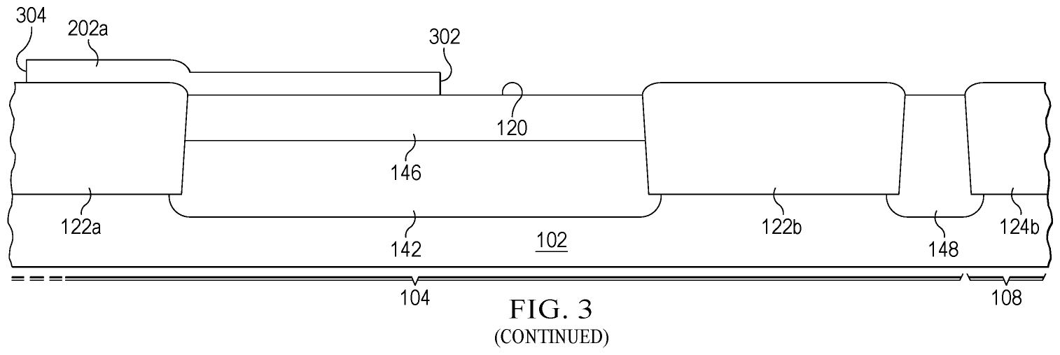

Referring to FIG. 3, the pedestal dielectric layer 202 is etched resulting in the pedestal dielectric layer 202a being in the BJT region 104. The pedestal dielectric layer 202 may be etched using appropriate photolithography and etching processes. For example, an anisotropic etch, such as an RIE, may be implemented. The pedestal dielectric layer 202a is over the upper surface 120 of the semiconductor substrate 102 in the BJT region 104 and extends laterally such that a sidewall 302 of the pedestal dielectric layer 202a is positioned over the upper surface 120 of the semiconductor substrate 102 in the BJT region 104. The pedestal dielectric layer 202a is over the first portion 122a of the isolation structure 122 in the BJT region 104 and extends laterally such that a sidewall 304 of the pedestal dielectric layer 202a is positioned over the first portion 122a of the isolation structure 122 in the BJT region 104.

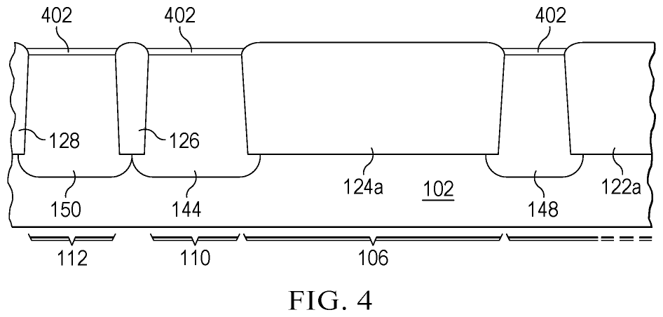

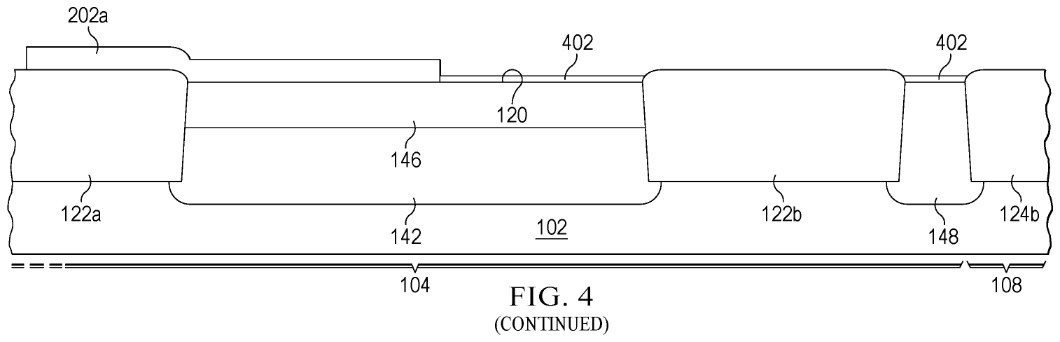

Referring to FIG. 4, a gate dielectric layer 402 is formed over the upper surface of the semiconductor substrate 102. In the illustrated example, the gate dielectric layer 402 is formed on exposed portions of the upper surface 120 of the semiconductor substrate 102 in the BJT region 104, pFET region 110, and nFET region 112. In the illustrated example, the gate dielectric layer 402 may be formed by an oxidation process, such as in situ steam generation (ISSG), which oxidizes the exposed portions of the upper surface 120 of the semiconductor substrate 102 to form an oxide as the gate dielectric layer 402. In other examples, other dielectric materials may be formed using an appropriate deposition process, which may conformally deposit the gate dielectric layer over the semiconductor substrate 102.

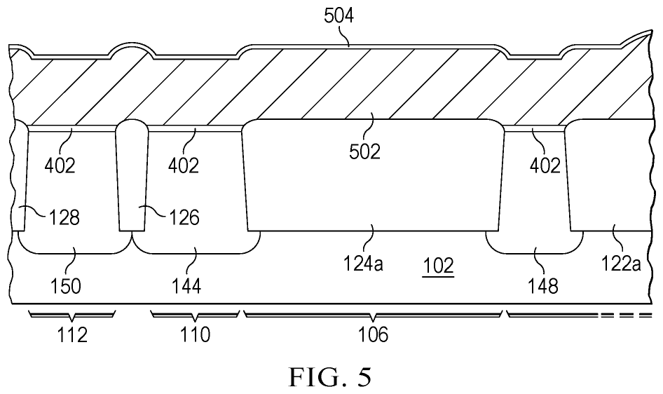

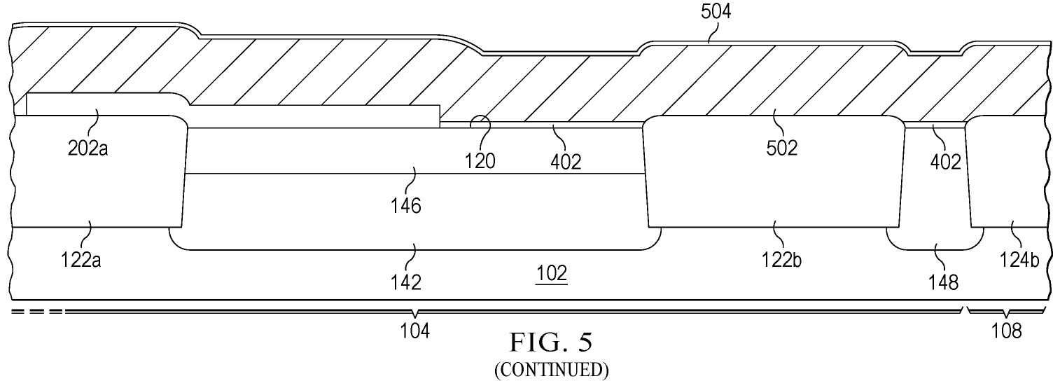

Referring to FIG. 5, a gate layer 502 is formed over the semiconductor substrate 102, and a dielectric protective layer 504 is formed over the gate layer 502. The gate layer 502 is formed over the gate dielectric layer 402, the isolation structures 122-128, and the pedestal dielectric layer 202a. In some examples, the gate layer 502 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. In some examples, the gate layer 502 is polysilicon doped with a p-type dopant with a concentration in a range from 1×10¹⁹ cm⁻³ to 1×10²¹ cm⁻³ after deposition and/or implantation. Other materials (e.g., conductive material) may be implemented as the gate layer 502, which may be formed by any deposition process. In some examples, the dielectric protective layer 504 is silicon oxide (e.g., a TEOS oxide) deposited by CVD, although other dielectric materials and/or other deposition processes may be used in other examples.

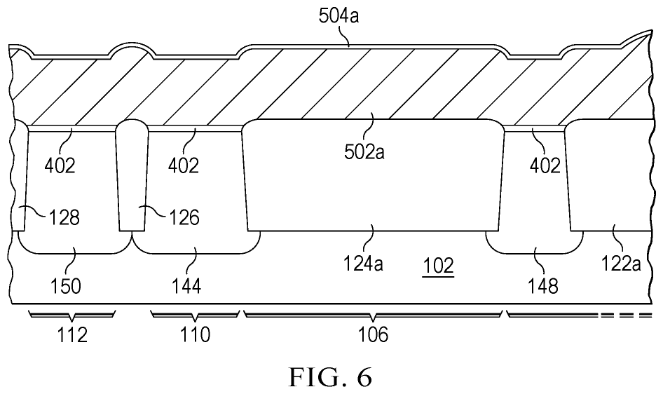

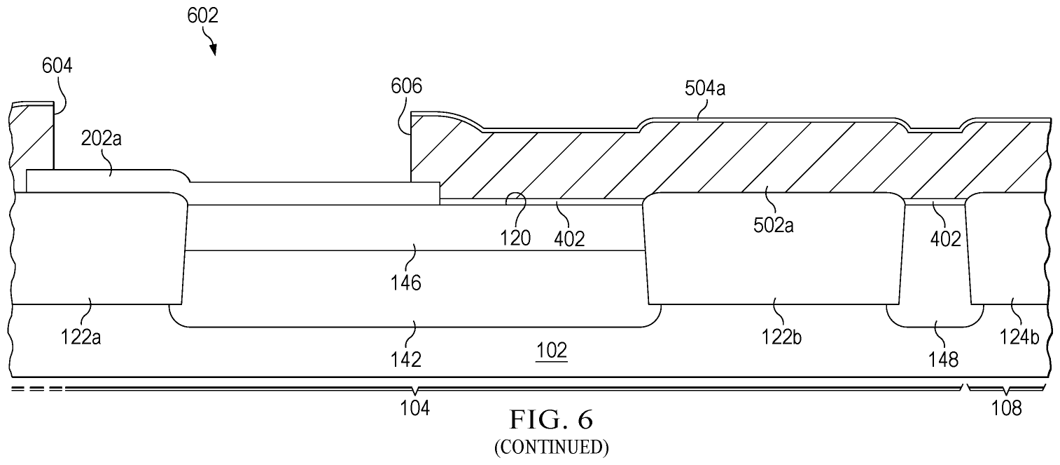

Referring to FIG. 6, the dielectric protective layer 504 and gate layer 502 are etched to form an opening 602 through the dielectric protective layer 504a and gate layer 502a to the pedestal dielectric layer 202a. The opening 602 is in the BJT region 104. The opening 602 is defined, at least in part, by sidewalls 604, 606 of the gate layer 502a (and further by corresponding sidewalls of the dielectric protective layer 504a, which are not indicated by a reference numeral). The sidewall 604 of the gate layer 502a is over the pedestal dielectric layer 202a and the first portion 122a of the isolation structure 122 in the BJT region 104. The sidewall 606 of the gate layer 502a is over the pedestal dielectric layer 202a in the BJT region 104. As will be shown subsequently, the BJT is formed through the opening 602 through the gate layer 502a. The dielectric protective layer 504 and gate layer 502 may be etched using appropriate photolithography and etching processes. For example, an anisotropic etch, such as an RIE, may be implemented.

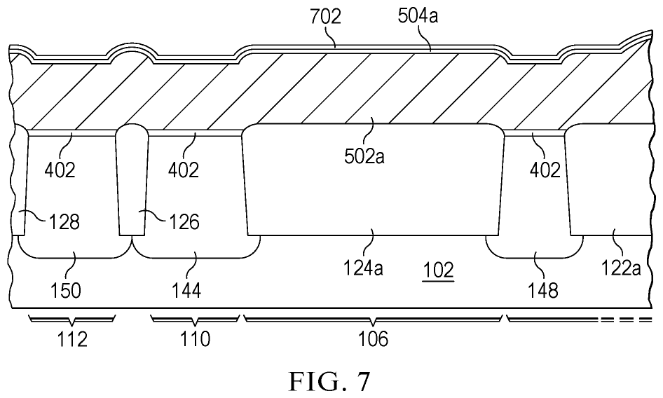

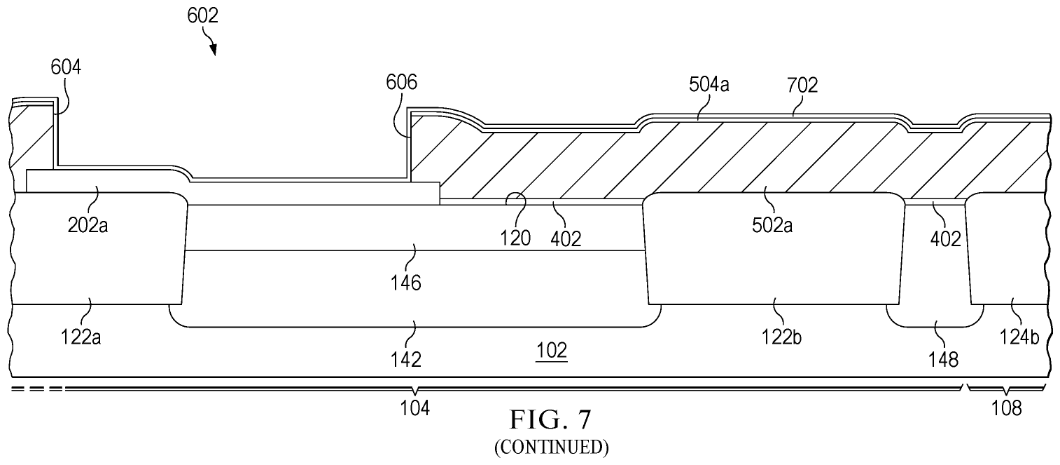

Referring to FIG. 7, a hardmask layer 702 is formed conformally over the semiconductor substrate 102. The hardmask layer 702 is conformally over the dielectric protective layer 504a, along the sidewalls 604, 606, and over the pedestal dielectric layer 202a exposed through the opening 602. In some examples, the hardmask layer 702 is or includes silicon nitride deposited by CVD, although other hardmask (e.g., dielectric) materials and/or other deposition processes may be used in other examples.

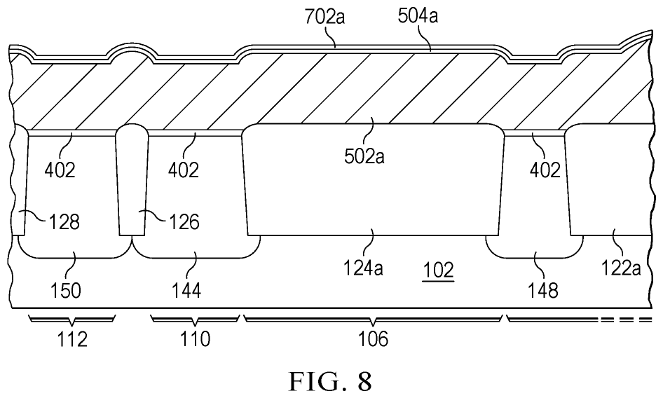

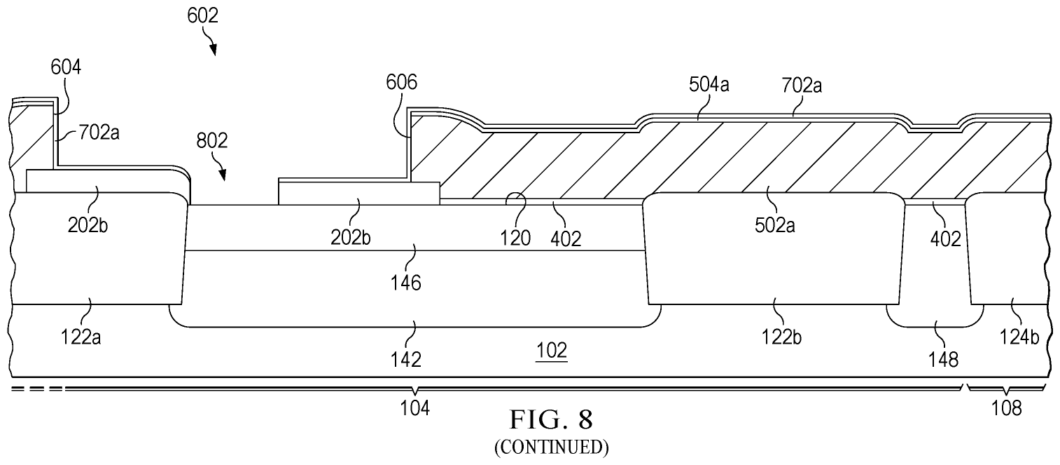

Referring to FIG. 8, the hardmask layer 702 and the pedestal dielectric layer 202a are etched to form a collector opening 802 through the hardmask layer 702a and the pedestal dielectric layer 202b. The hardmask layer 702 and the pedestal dielectric layer 202a are etched through the opening 602 to form the collector opening 802. The upper surface 120 of the semiconductor substrate 102 is exposed through the collector opening 802. The collector opening 802 generally extends from proximate to (or some lateral distance from) the first portion 122a of the isolation structure 122 laterally away from the first portion 122a of the isolation structure 122 in the BJT region 104. The hardmask layer 702 and the pedestal dielectric layer 202a may be etched using appropriate photolithography and etching processes. For example, an anisotropic etch, such as an RIE, may be implemented.

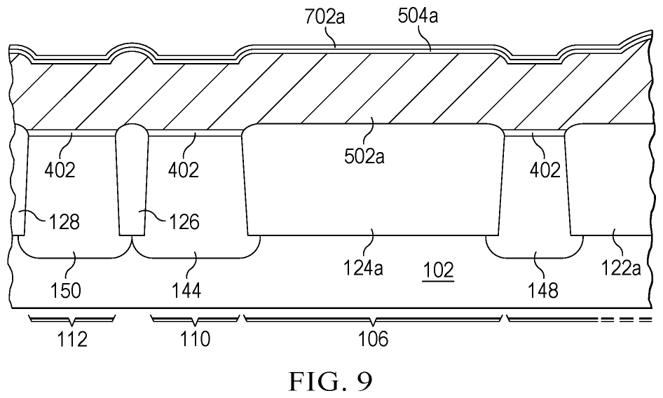

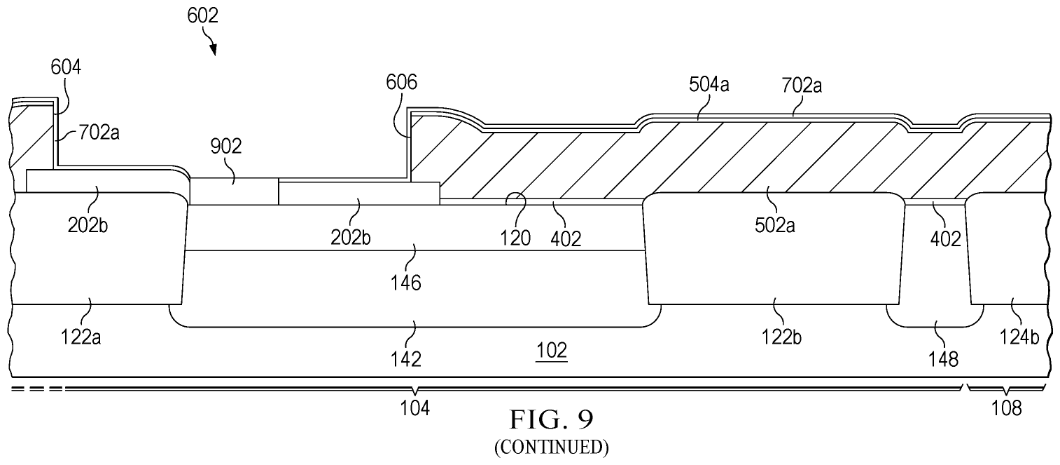

Referring to FIG. 9, a collector layer 902 is formed over (e.g., on) the upper surface 120 of the semiconductor substrate 102 and in the collector opening 802. In some examples, the collector layer 902 is or includes a semiconductor layer doped with an n-type dopant (e.g., a same dopant type as the n-type doped sub-collector diffusion region 146). In some examples, the collector layer 902 is or includes silicon. In some examples, the collector layer 902 is doped with an n-type dopant with a concentration in a range from 1×10¹⁹ cm⁻³ to 1×10²¹ cm⁻³. The collector layer 902 may be epitaxially grown on the upper surface 120 of the semiconductor substrate 102. The collector layer 902 may be epitaxially grown by a selective epitaxial growth process in some examples. The epitaxial growth of the collector layer 902 on the upper surface 120 of the semiconductor substrate 102 may result in the collector layer 902 being monocrystalline. Further, the collector layer 902 may be in situ doped during the epitaxial growth process (e.g., the selective epitaxial growth process). The epitaxial growth process may be a CVD process, such as a low pressure CVD (LPCVD), reduced pressure CVD (RPCVD), metal organic CVD (MOCVD), or the like. Other materials, dopant type, dopant concentration, and/or deposition process may be implemented.

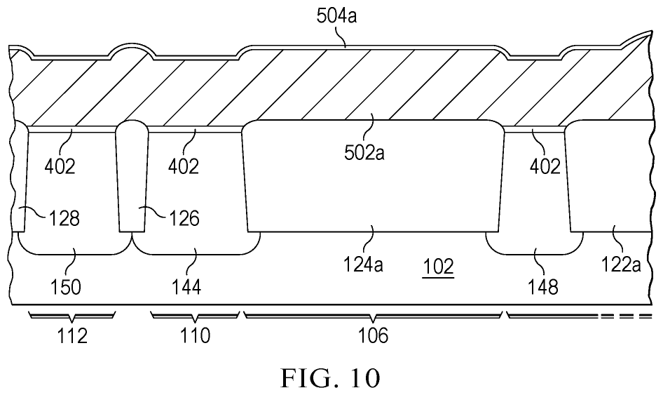

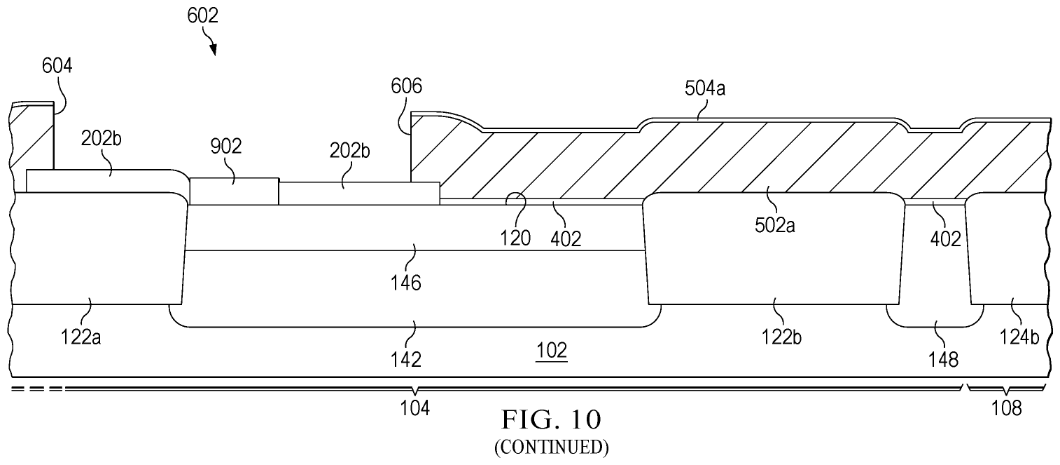

Referring to FIG. 10, the hardmask layer 702a is removed. The hardmask layer 702a may be removed using an etch selective to the material of the hardmask layer 702a, which may be a wet etch process. For example, when the hardmask layer 702a is silicon nitride, the hardmask layer 702a may be removed using a wet etch process that includes phosphoric acid (H₃PO₄).

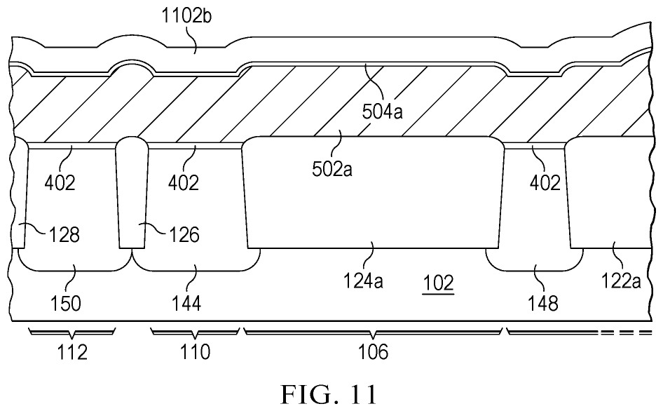

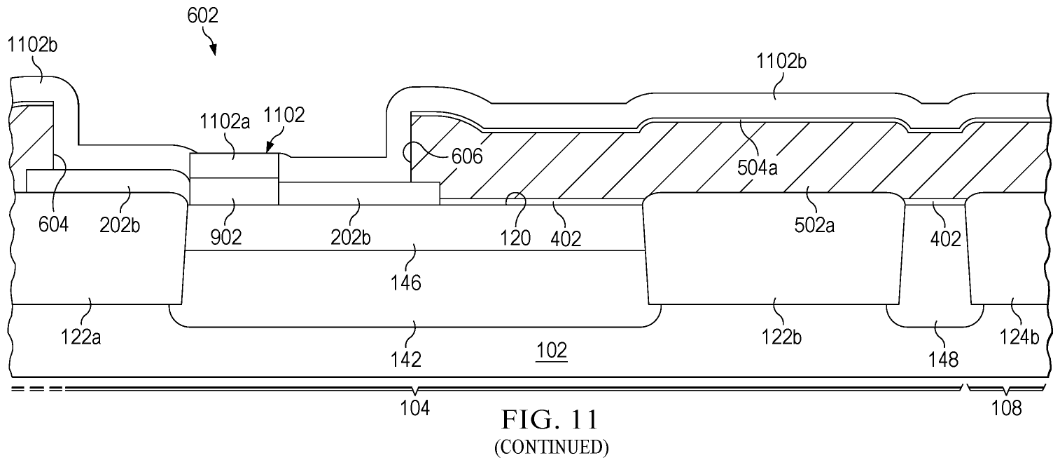

Referring to FIG. 11, a base layer 1102 is formed over the collector layer 902. The base layer 1102 includes a monocrystalline base layer 1102a and a polycrystalline base layer 1102b. The monocrystalline base layer 1102a and polycrystalline base layer 1102b together form the base layer 1102. In some examples, the base layer 1102 is or includes a semiconductor layer doped with a p-type dopant (e.g., an opposite dopant type as the collector layer 902). In some examples, the base layer 1102 is or includes silicon germanium. In some examples, the base layer 1102 is doped with a p-type dopant with a concentration in a range from 1×10¹⁷ cm⁻³ to 1×10²¹ cm⁻³. The base layer 1102 may also be doped with carbon (C) to prevent or reduce diffusion of the p-type dopant. The base layer 1102 may be epitaxially grown on the collector layer 902, the pedestal dielectric layer 202b, the gate layer 502a, and the dielectric protective layer 504a. The base layer 1102 may be epitaxially grown by a non-selective epitaxial growth process in some examples. The non-selective epitaxial growth process grows the monocrystalline base layer 1102a from the collector layer 902 and grows the polycrystalline base layer 1102b on other amorphous or polycrystalline surfaces, such as the pedestal dielectric layer 202b. The monocrystalline base layer 1102a may meet the polycrystalline base layer 1102b at a facet that is not specifically illustrated. The non-selective deposition of the base layer 1102 forms the base layer 1102 conformally in the opening 602 and on the dielectric protective layer 504a outside of the opening 602. The base layer 1102 may be in situ doped during the epitaxial growth process. The base layer 1102 (e.g., the monocrystalline base layer 1102a and polycrystalline base layer 1102b each) may further include multiple sub-layers, such as a nucleation sub-layer of the same material as the collector layer 902, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

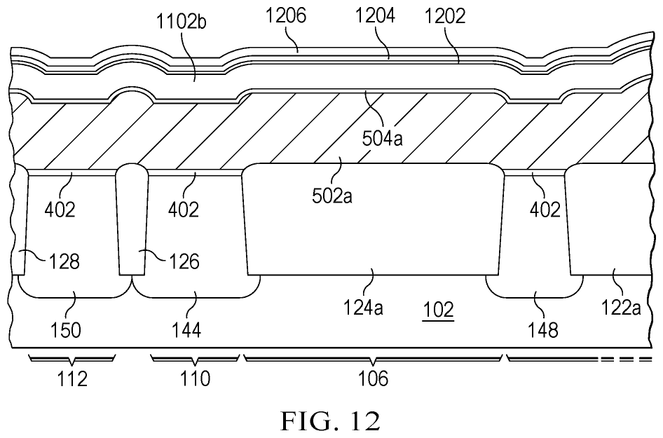

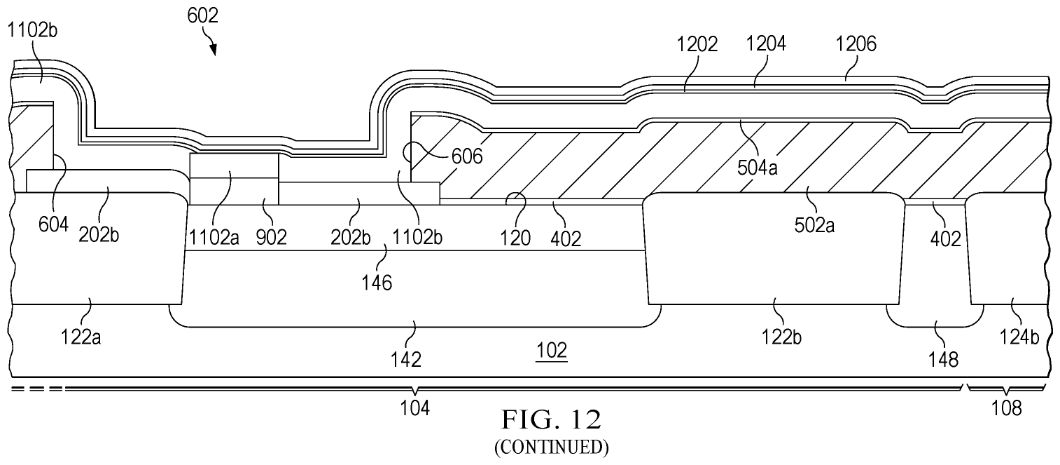

Referring to FIG. 12, a first dielectric spacer layer 1202 is formed conformally over the base layer 1102. A second dielectric spacer layer 1204 is formed conformally over the first dielectric spacer layer 1202, and a third dielectric spacer layer 1206 is formed conformally over the second dielectric spacer layer 1204. In some examples, the first dielectric spacer layer 1202 and third dielectric spacer layer 1206 are a same dielectric material, and the second dielectric spacer layer 1204 is a dielectric material different from the dielectric material of the first and third dielectric spacer layers 1202, 1206. In some examples, the first and third dielectric spacer layers 1202, 1206 are silicon oxide (e.g., a TEOS oxide), and the second dielectric spacer layer 1204 is silicon nitride. The dielectric spacer layers 1202-1206 may be deposited by CVD. Other dielectric materials and/or other deposition processes may be used in other examples.

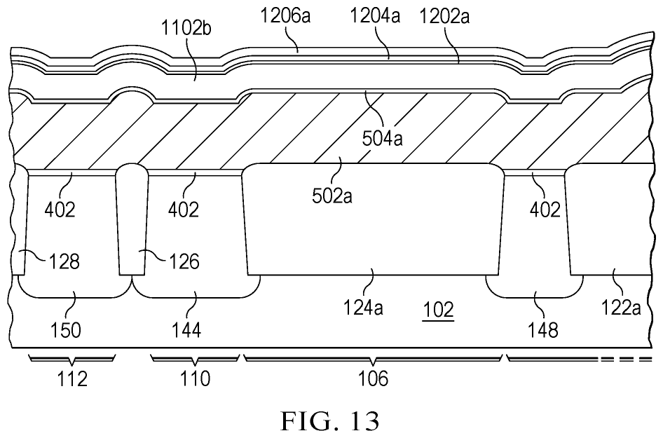

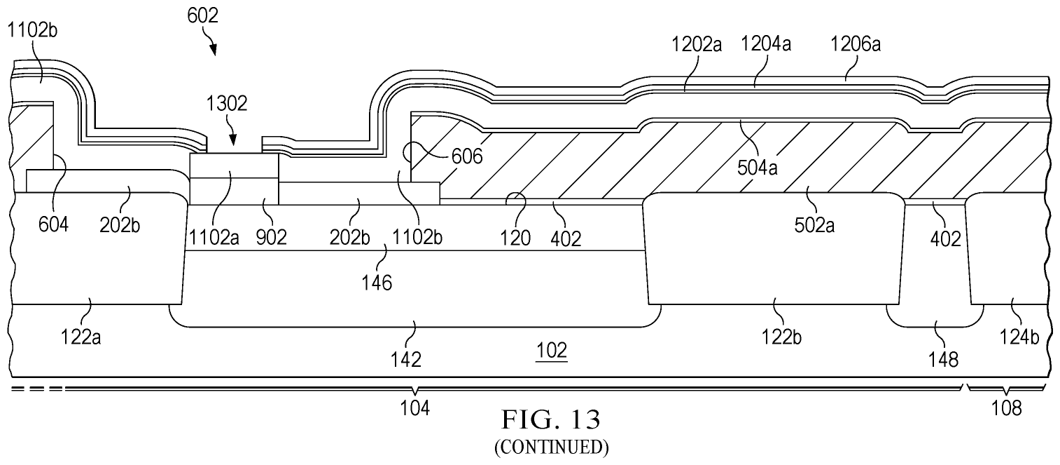

Referring to FIG. 13, the dielectric spacer layers 1202-1206 are etched to form a first emitter opening 1302 through the first dielectric spacer layer 1202a, second dielectric spacer layer 1204a, and third dielectric spacer layer 1206a. The dielectric spacer layers 1202-1206 are etched through the opening 602 to form the first emitter opening 1302. The monocrystalline base layer 1102a (of the base layer 1102) is exposed through the first emitter opening 1302. The first emitter opening 1302 is in the BJT region 104. The dielectric spacer layers 1202-1206 may be etched using appropriate photolithography and etching processes. For example, an anisotropic etch, such as an RIE, may be implemented.

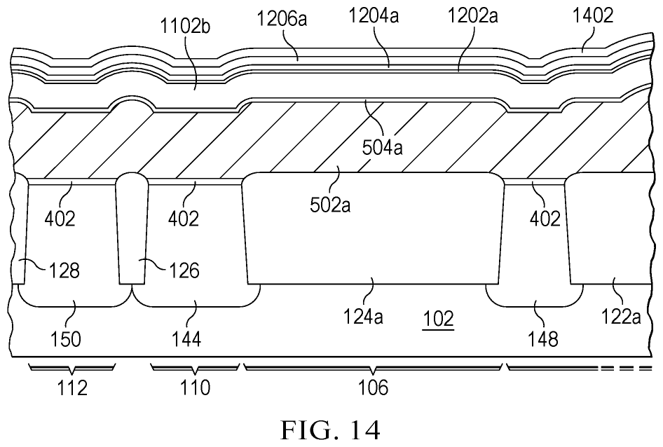

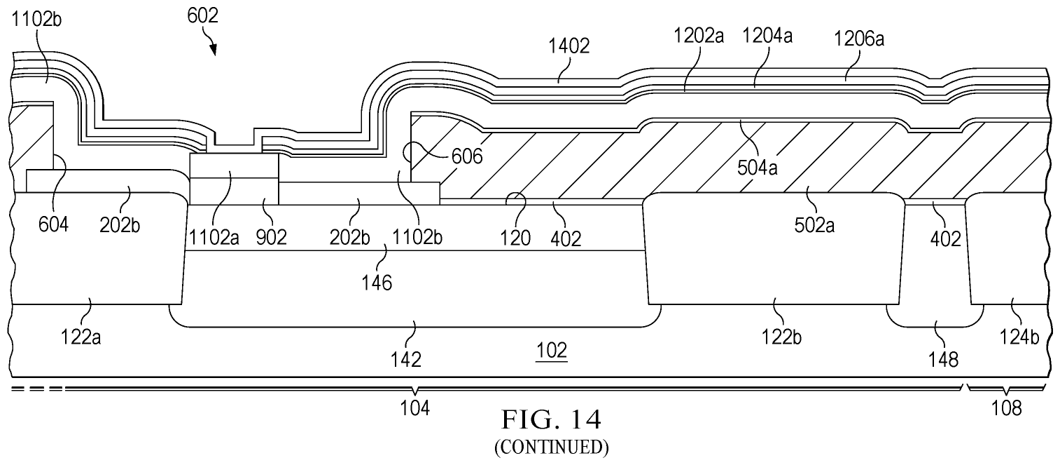

Referring to FIG. 14, an emitter dielectric spacer layer 1402 is conformally formed over the third dielectric spacer layer 1206a and in the first emitter opening 1302. In some examples, the emitter dielectric spacer layer 1402 is silicon oxide (e.g., a TEOS oxide) deposited by CVD, although other dielectric materials and/or other deposition processes may be used in other examples.

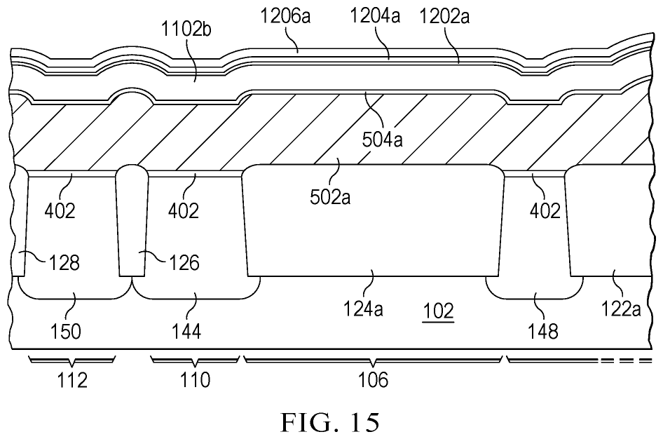

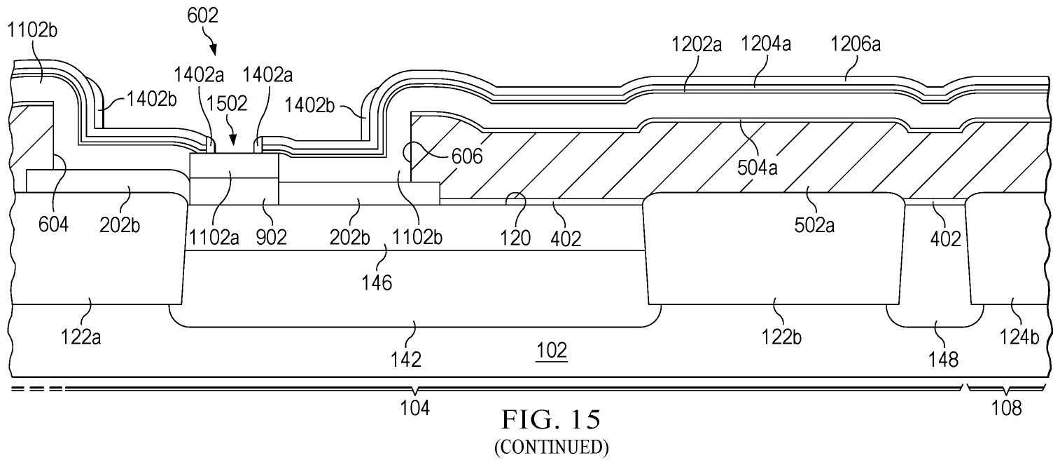

Referring to FIG. 15, the emitter dielectric spacer layer 1402 is anisotropically etched to form emitter dielectric spacers 1402a along sidewalls that define the first emitter opening 1302. The emitter dielectric spacers 1402a constrict the first emitter opening 1302 to form a second emitter opening 1502. Additionally, residual dielectric spacers 1402b remain on vertical surfaces of the third dielectric spacer layer 1206a. The anisotropic etch may be an RIE, for example.

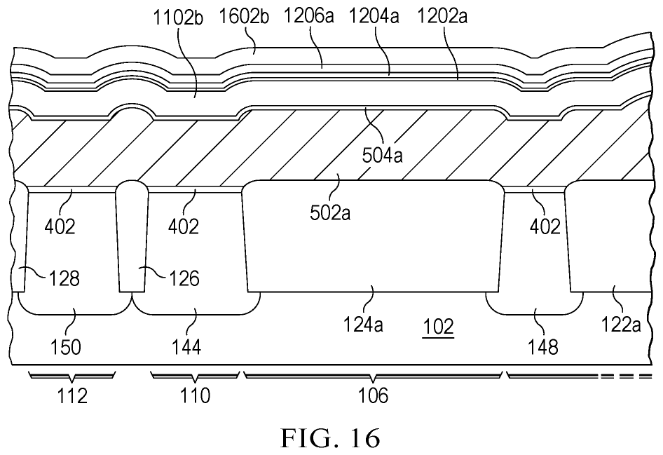

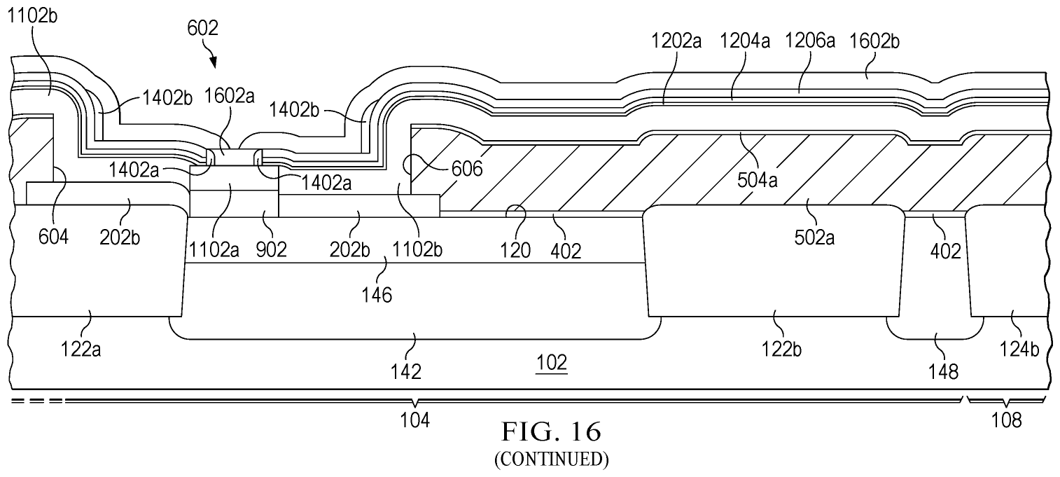

Referring to FIG. 16, an emitter layer 1602 is formed over the base layer 1102 (e.g., on the monocrystalline base layer 1102a). The emitter layer 1602 includes a monocrystalline emitter layer 1602a and a polycrystalline emitter layer 1602b. The monocrystalline emitter layer 1602a and polycrystalline emitter layer 1602b together form the emitter layer 1602. In some examples, the emitter layer 1602 is or includes a semiconductor layer doped with an n-type dopant (e.g., an opposite dopant type from the base layer 1102). In some examples, the emitter layer 1602 is or includes silicon. In some examples, the emitter layer 1602 is doped with an n-type dopant with a concentration in a range from 1×10¹⁹ cm⁻³ to 1×10²¹ cm⁻³. The emitter layer 1602 may be epitaxially grown on the base layer 1102 (e.g., the monocrystalline base layer 1102a) exposed through the second emitter opening 1502, the emitter dielectric spacers 1402a, and the third dielectric spacer layer 1206a. The emitter layer 1602 may be epitaxially grown by a non-selective epitaxial growth process in some examples. The non-selective epitaxial growth process grows the monocrystalline emitter layer 1602a from the monocrystalline base layer 1102a and grows the polycrystalline emitter layer 1602b on other amorphous or polycrystalline surfaces, such as the emitter dielectric spacers 1402a and the third dielectric spacer layer 1206a. The monocrystalline emitter layer 1602a may meet the polycrystalline emitter layer 1602b at a facet that is not specifically illustrated. The non-selective deposition of the emitter layer 1602 forms the emitter layer 1602 conformally in the opening 602 and on the third dielectric spacer layer 1206a outside of the opening 602. The emitter layer 1602 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

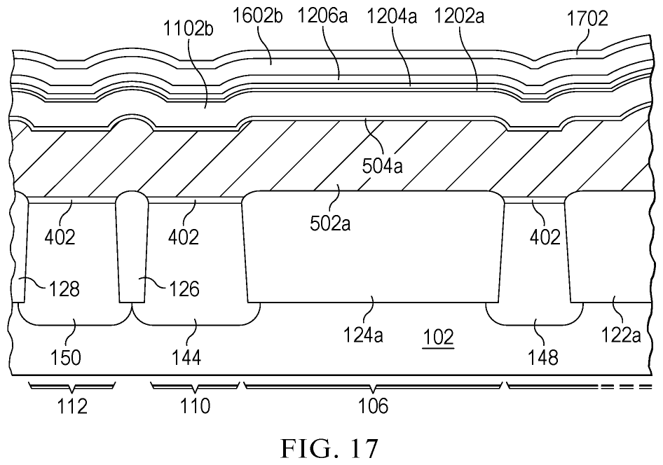

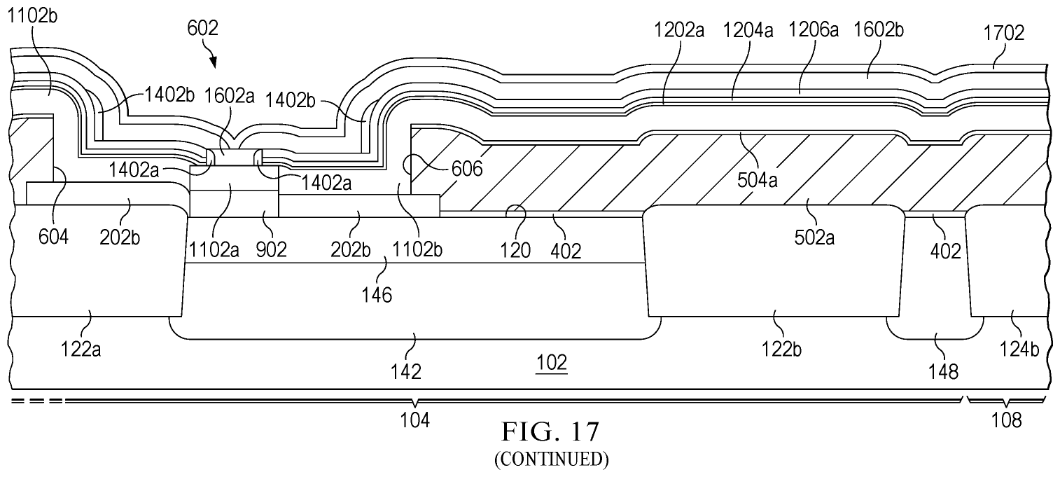

Referring to FIG. 17, an emitter dielectric cap layer 1702 is conformally formed over the emitter layer 1602. In some examples, the emitter dielectric cap layer 1702 is silicon oxide (e.g., a TEOS oxide) deposited by CVD, although other dielectric materials and/or other deposition processes may be used in other examples.

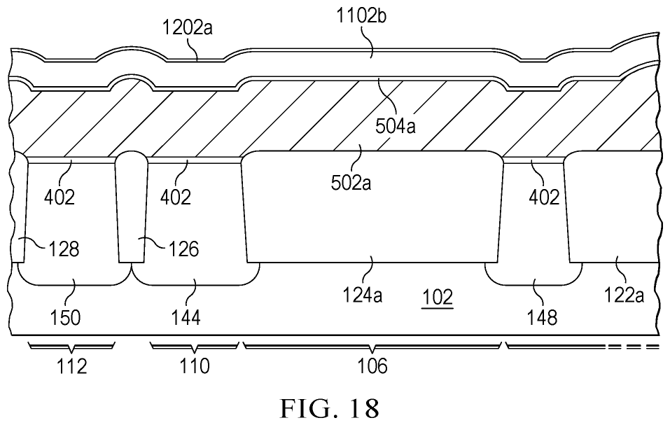

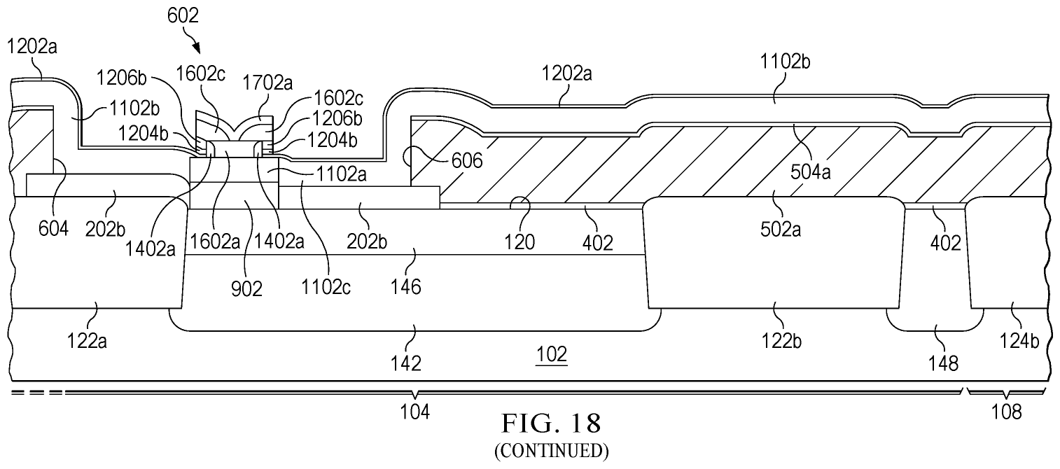

Referring to FIG. 18, the emitter dielectric cap layer 1702, polycrystalline emitter layer 1602b, third dielectric spacer layer 1206a, and second dielectric spacer layer 1204a are etched to form the emitter dielectric cap layer 1702a, polycrystalline emitter layer 1602c, third dielectric spacer 1206b, and second dielectric spacer 1204b in the opening 602. The layers 1702, 1602b, 1206a, 1204a may be etched using appropriate photolithography and etching processes. For example, an anisotropic etch, such as an RIE, may be implemented.

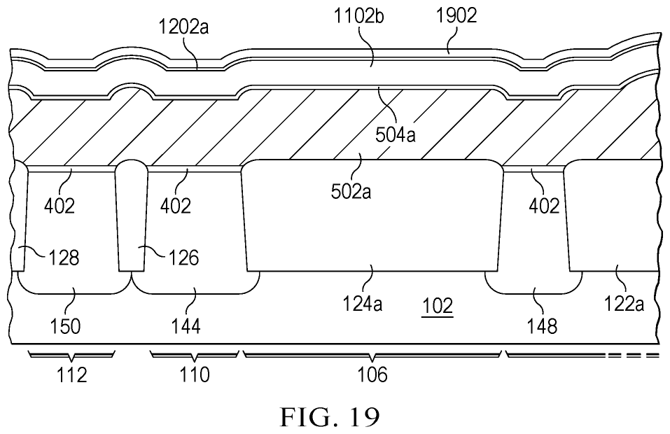

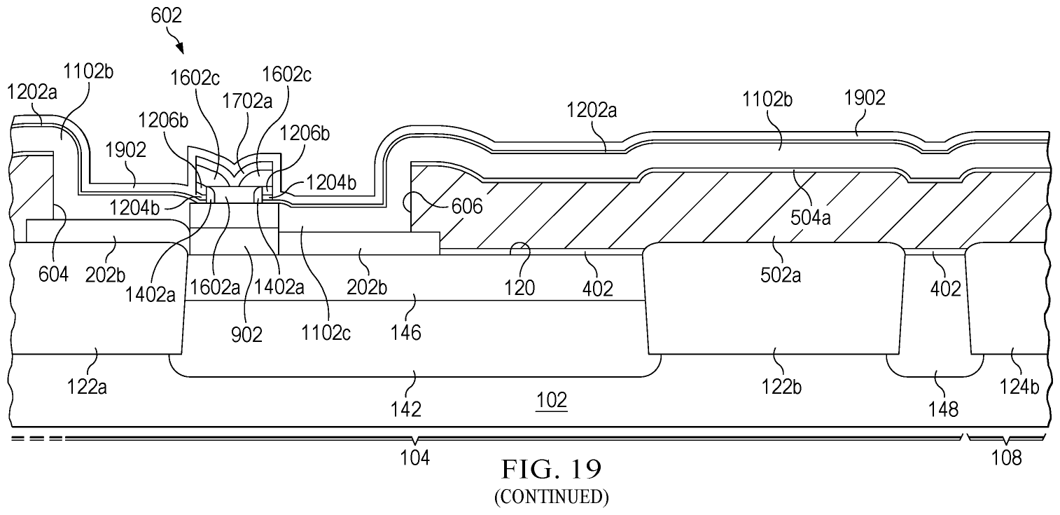

Referring to FIG. 19, an emitter dielectric protective spacer layer 1902 is conformally formed over the emitter dielectric cap layer 1702a and the second dielectric spacer layer 1204a and along sidewalls of the emitter dielectric cap layer 1702a, polycrystalline emitter layer 1602c, third dielectric spacer 1206b, and second dielectric spacer 1204b. In some examples, the emitter dielectric protective spacer layer 1902 is silicon oxide (e.g., a TEOS oxide) deposited by CVD, although other dielectric materials and/or other deposition processes may be used in other examples.

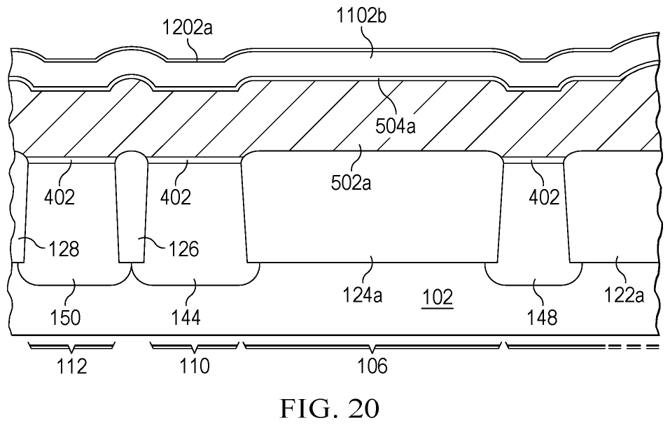

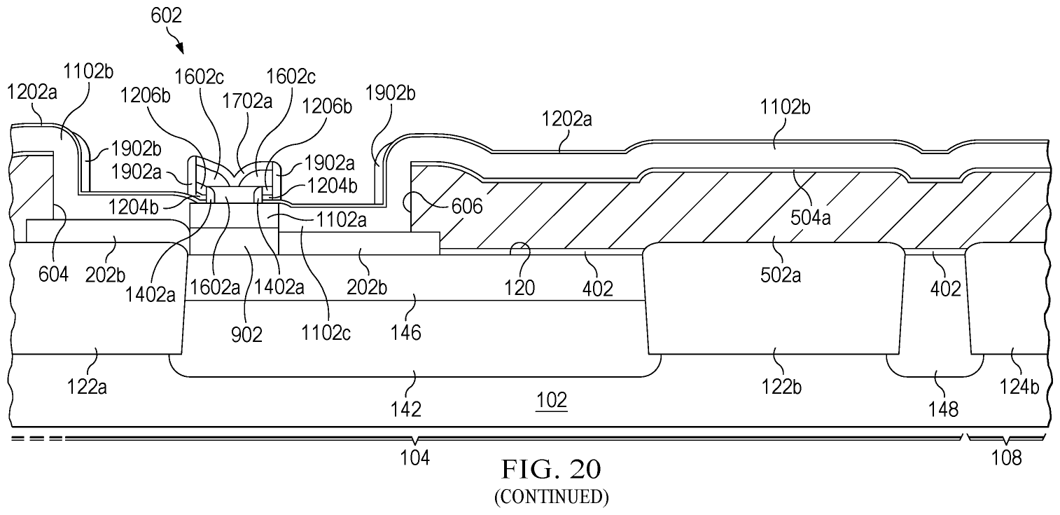

Referring to FIG. 20, the emitter dielectric protective spacer layer 1902 is anisotropically etched to form emitter dielectric protective spacers 1902a along sidewalls of the emitter dielectric cap layer 1702a, polycrystalline emitter layer 1602c, third dielectric spacer 1206b, and second dielectric spacer 1204b. The emitter dielectric protective spacers 1902a protect sidewalls of the polycrystalline emitter layer 1602c. Additionally, residual dielectric spacers 1902b remain on vertical surfaces of the first dielectric spacer layer 1202a. The anisotropic etch may be an RIE, for example.

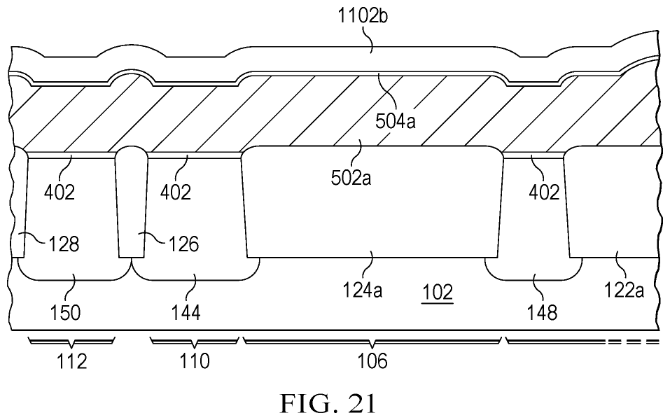

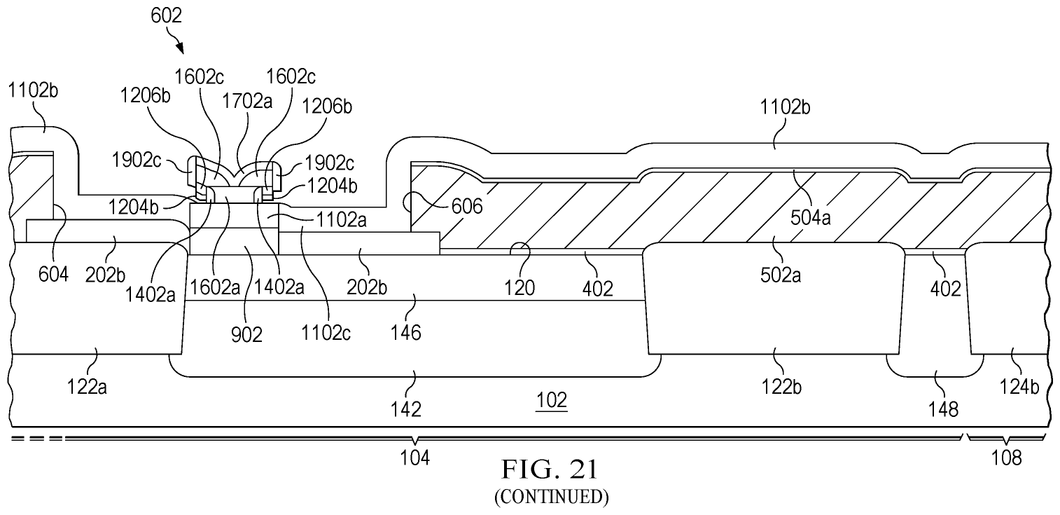

Referring to FIG. 21, the first dielectric spacer layer 1202a is removed. The first dielectric spacer layer 1202a may be removed by masking (e.g., by a photoresist using photolithography) the emitter dielectric cap layer 1702a and the emitter dielectric protective spacers 1902a and performing a wet etch selective to the first dielectric spacer layer 1202a. For example, when the first dielectric spacer layer 1202a is silicon oxide, the first dielectric spacer layer 1202a may be removed using a dilute hydrochloric acid (dHCl) etch. A wet etch may undercut the mask to remove the first dielectric spacer layer 1202a that underlies the emitter dielectric protective spacers 1902a and the second dielectric spacers 1204b. Additionally, the wet etch undercutting the mask may further etch a lower portion of the emitter dielectric protective spacers 1902a, which results in emitter dielectric protective spacers 1902c, when the emitter dielectric protective spacers 1902a are a same material as the first dielectric spacer layer 1202a, such as illustrated. Further, the wet etch may remove the residual dielectric spacers 1902b.

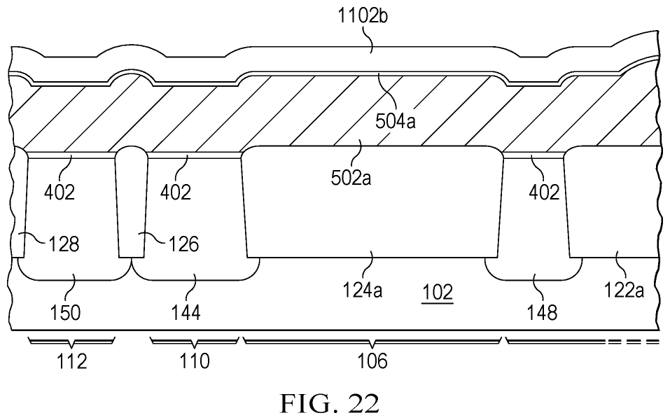

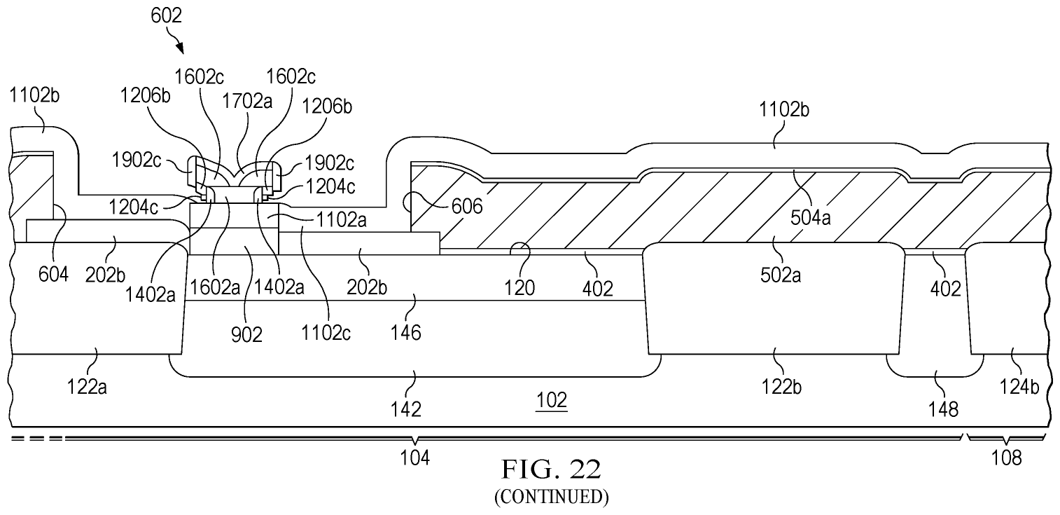

Referring to FIG. 22, a pullback etch of the second dielectric spacers 1204b is performed. The pullback etch pulls back the second dielectric spacers 1204b, which results in second dielectric spacers 1204c, under the third dielectric spacers 1206b laterally distal from the monocrystalline emitter layer 1602a. As illustrated subsequently, the removal of the first dielectric spacer layer 1202a and the pullback etch forming the second dielectric spacers 1204c open (e.g., expose) an area on the base layer 1102 near the monocrystalline emitter layer 1602a on which a raised base layer may be formed. The pullback etch may be a wet etch selective to the material of the second dielectric spacers 1204b. For example, when the second dielectric spacers 1204b are silicon nitride, the wet etch may include phosphoric acid.

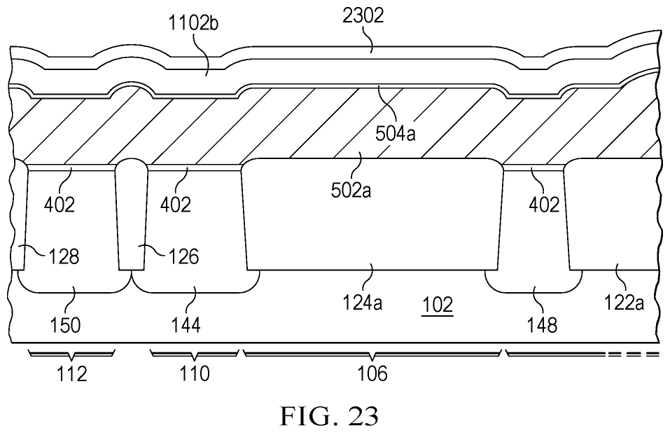

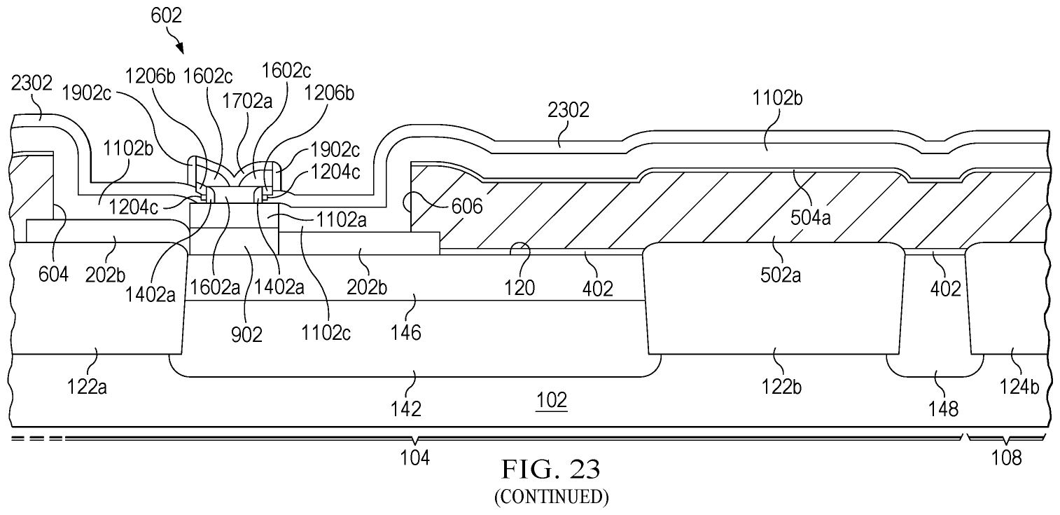

Referring to FIG. 23, a raised base layer 2302 is formed over the base layer 1102. The raised base layer 2302 includes at least a polycrystalline raised base layer on the polycrystalline base layer 1102b. The raised base layer 2302 may include a monocrystalline raised base layer. If the monocrystalline base layer 1102a is exposed by removing the first dielectric spacer layer 1202a and the pullback etch to form the second dielectric spacers 1204c, the raised base layer 2302 may include a monocrystalline portion on the monocrystalline base layer 1102a. In some examples, the raised base layer 2302 is or includes a semiconductor layer doped with a p-type dopant (e.g., a same dopant type as the base layer 1102). In some examples, the raised base layer 2302 is or includes silicon. In some examples, the raised base layer 2302 is doped with a p-type dopant with a concentration in a range from 1×10¹⁹ cm⁻³ to 1×10²¹ cm⁻³. The raised base layer 2302 may be epitaxially grown on the base layer 1102. The raised base layer 2302 may be epitaxially grown by a selective epitaxial growth process in some examples. The selective deposition of the raised base layer 2302 forms the raised base layer 2302 conformally on crystalline (e.g., polycrystalline and monocrystalline) surfaces in and outside of the opening 602 (e.g., on the base layer 1102). Further, the raised base layer 2302 may be in situ doped during the epitaxial growth process (e.g., the selective epitaxial growth process). The epitaxial growth process may be a CVD process, such as LPCVD, RPCVD, MOCVD, or the like. Other materials, dopant type, dopant concentration, and/or deposition process may be implemented.

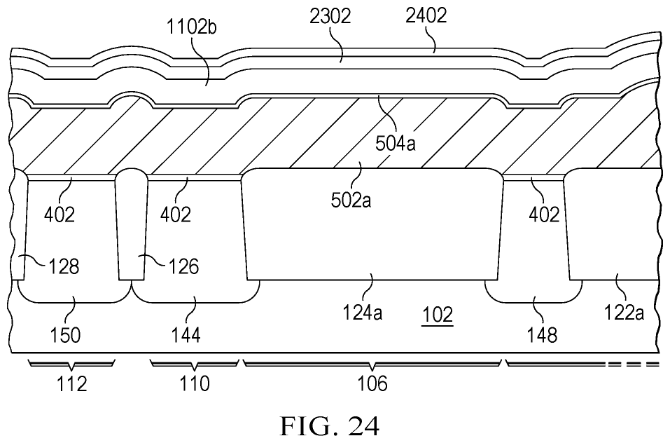

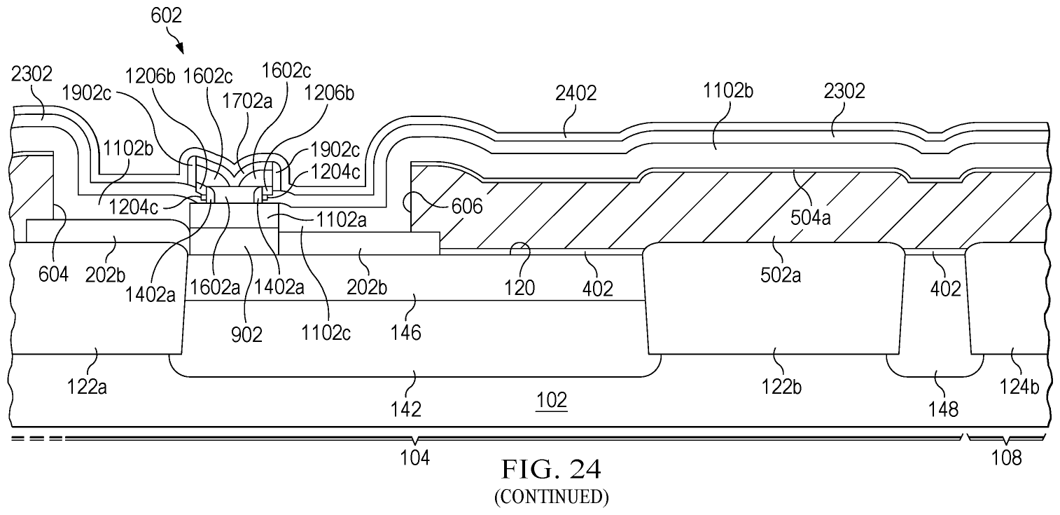

Referring to FIG. 24, a dielectric protective layer 2402 is conformally formed over and along the emitter dielectric cap layer 1702a, the emitter dielectric protective spacers 1902c, and the raised base layer 2302. In some examples, the dielectric protective layer 2402 is silicon oxide (e.g., a TEOS oxide) deposited by CVD, although other dielectric materials and/or other deposition processes may be used in other examples.

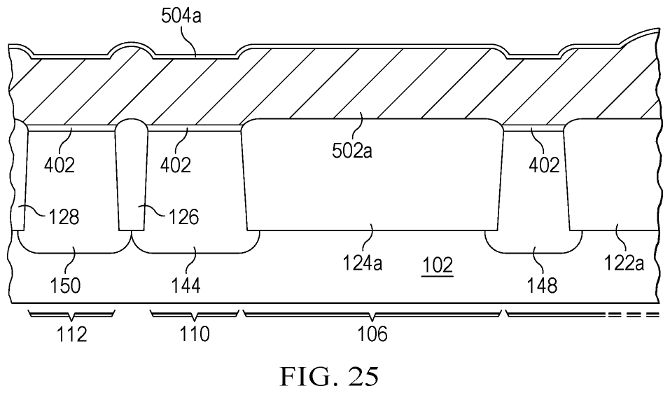

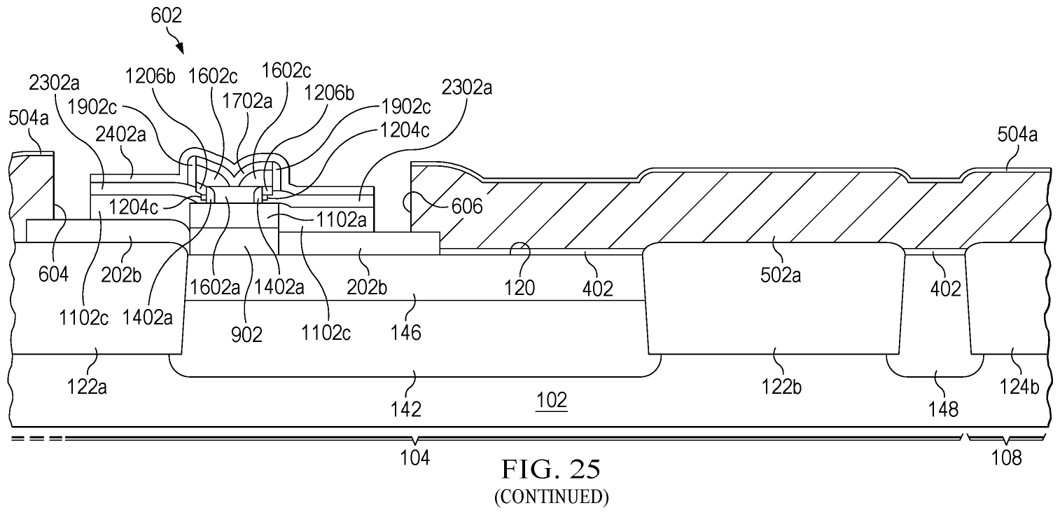

Referring to FIG. 25, the dielectric protective layer 2402, the raised base layer 2302, and the base layer 1102 (e.g., the polycrystalline base layer 1102b) are patterned. The raised base layer 2302 and the polycrystalline base layer 1102b are patterned to remain as the raised base layer 2302a and polycrystalline base layer 1102c within the opening 602. The dielectric protective layer 2402, the raised base layer 2302, and the base layer 1102 outside of the opening 602, and more specifically, outside of the BJT region 104, are removed by the patterning. Hence, the base layer 1102 and raised base layer 2302 are removed from the sidewalls 604, 606 of the gate layer 502a and from over the dielectric protective layer 504a. The pedestal dielectric layer 202b extends laterally from the polycrystalline base layer 1102c over the first portion 122a of the isolation structure 122 and extends laterally from the polycrystalline base layer 1102c over the upper surface 120 of the semiconductor substrate 102 in the BJT region 104. The dielectric protective layer 2402, raised base layer 2302, and base layer 1102 may be patterned using appropriate photolithography and etching processes. For example, an anisotropic etch, such as an RIE, may be implemented.

In subsequent processing for forming the nFET and the pFET, a lower thermal budget may be implemented. The lower thermal budget may mitigate against relaxation of the monocrystalline base layer 1102a when the monocrystalline base layer 1102a is a material dissimilar from the collector layer 902. The lower thermal budget may also mitigate against diffusion of dopants between the collector layer 902, base layer 1102, and/or emitter layer 1602. Examples of such thermal processing with a lower thermal budget are provided below.

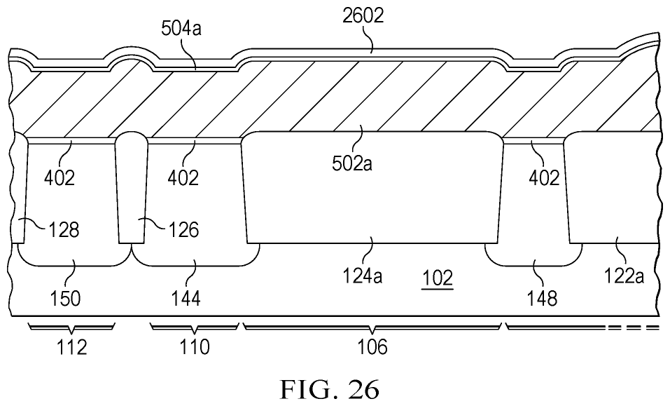

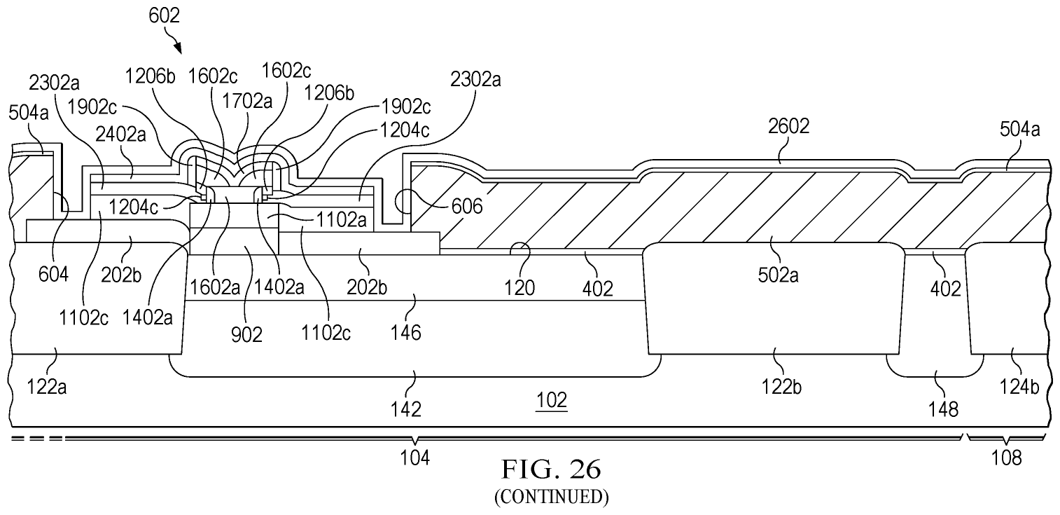

Referring to FIG. 26, a hardmask layer 2602 is conformally formed over the dielectric protective layer 504a and in the opening 602. The hardmask layer 2602 is conformally over the dielectric protective layer 504a, along the sidewalls 604, 606, and over the pedestal dielectric layer 202a, base layer 1102, raised base layer 2302a, and dielectric protective layer 2402a exposed through the opening 602. In some examples, the hardmask layer 2602 is or includes silicon nitride deposited by CVD, although other hardmask (e.g., dielectric) materials and/or other deposition processes may be used in other examples.

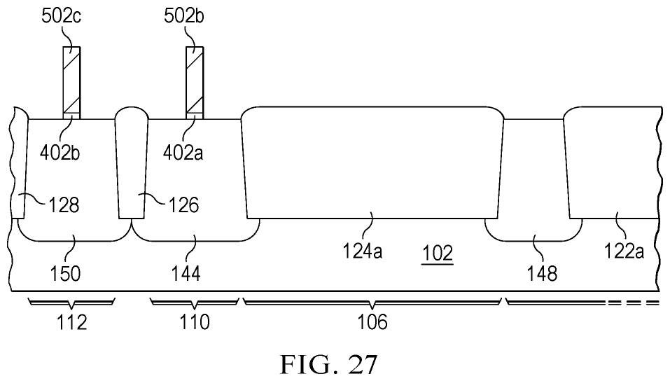

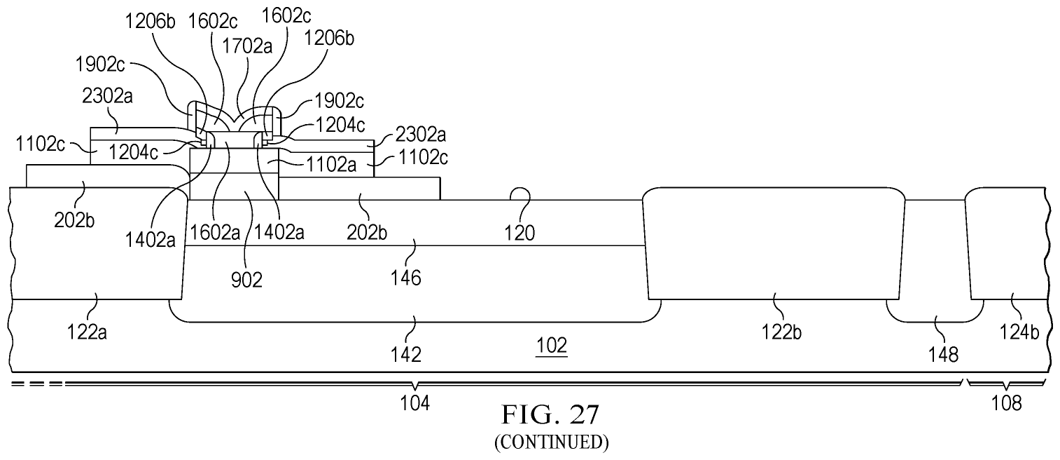

Referring to FIG. 27, the gate layer 502a is patterned into gate electrodes 502b, 502c, and the gate dielectric layer 402 is patterned into gate dielectric layers 402a, 402b. The hardmask layer 2602 is patterned corresponding to the pattern of the gate electrodes 502b, 502c, and using the patterned hardmask layer 2602 as a mask, the gate layer 502a and the gate dielectric layer 402 are patterned. The hardmask layer 2602 may be patterned using appropriate photolithography and etching processes, and the gate layer 502a and the gate dielectric layer 402 may be patterned using an appropriate etching process. For example, an anisotropic etch, such as an RIE, may be implemented. The gate electrode 502b is over (e.g., on) the gate dielectric layer 402a in the pFET region 110, and the gate electrode 502c is over (e.g., on) the gate dielectric layer 402b in the nFET region 112. Patterning the gate dielectric layer 402 removes the gate dielectric layer 402 from the upper surface 120 of the semiconductor substrate 102 in the BJT region 104. Thereafter, the patterned hardmask layer 2602, dielectric protective layer 504a, and dielectric protective layer 2402a are removed, such as by wet etches selective to the material of those layers. For example, when the hardmask layer 2602 is silicon nitride, a wet etch including phosphoric acid may remove the hardmask layer 2602, and when the dielectric protective layer 504a and dielectric protective layer 2402a are silicon oxide, a wet etch including diluted hydrochloric acid may remove the dielectric protective layer 504a and dielectric protective layer 2402a.

Although not illustrated, after removing the hardmask layer 2602 and the dielectric protective layer 504a, a protective oxide layer may be formed on the gate electrodes 502b, 502c. The protective oxide layer may be formed by an oxidation process, such as ISSG. In some examples with a lower thermal budget, the oxidation process may be performed at 750° C. or less for 5 seconds or less.

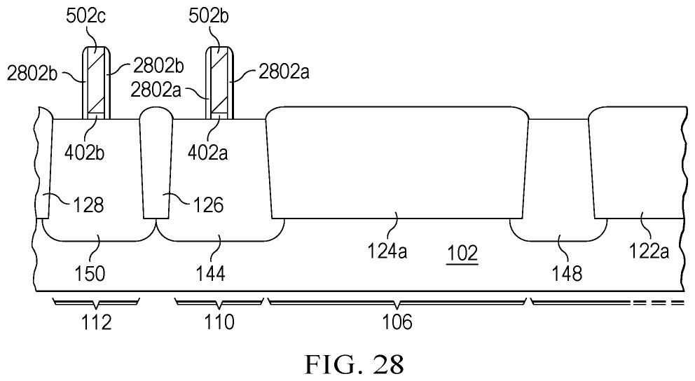

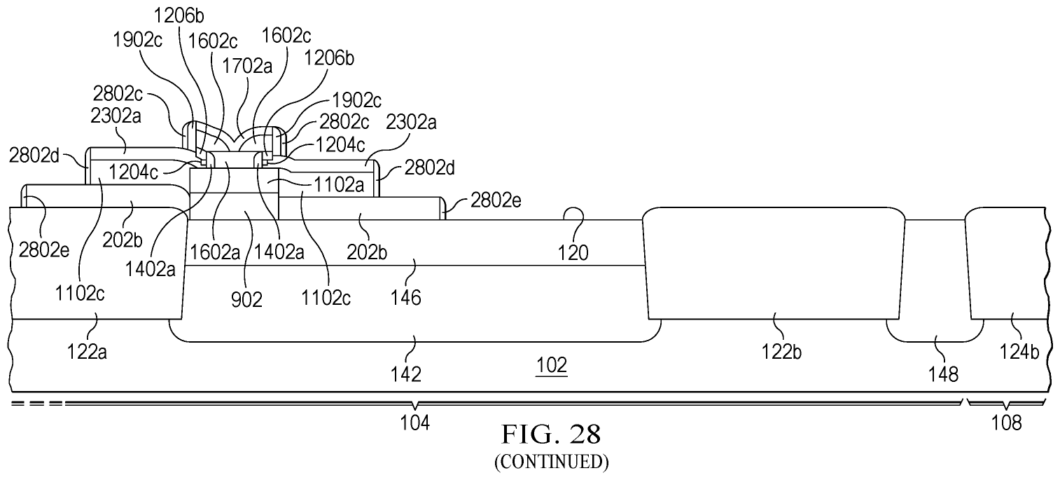

Referring to FIG. 28, first gate dielectric spacers 2802a. 2802b are formed along sidewalls of the gate electrodes 502b, 502c. The first gate dielectric spacers 2802a, 2802b may be formed by depositing a layer of the material of the first gate dielectric spacers 2802a, 2802b conformally over the semiconductor substrate 102 and anisotropically etching the layer such that the first gate dielectric spacers 2802a, 2802b remain. The material of the first gate dielectric spacers 2802a. 2802b may be any appropriate dielectric material, such as silicon nitride, silicon oxynitride, silicon carbon nitride, the like, or a combination thereof. The layer may be deposited by CVD, PECVD, atomic layer deposition (ALD), or the like. The formation of the first gate dielectric spacers 2802a, 2802b may further form residual dielectric spacers 2802c. 2802d, 2802e on sidewalls of components in the BJT region 104. For example, residual dielectric spacers 2802c are on respective sidewalls of the emitter dielectric protective spacers 1902c; residual dielectric spacers 2802d are formed on respective sidewalls of the polycrystalline base layer 1102c and raised base layer 2302a; and residual dielectric spacers 2802e are formed on respective sidewalls of the pedestal dielectric layer 202b.

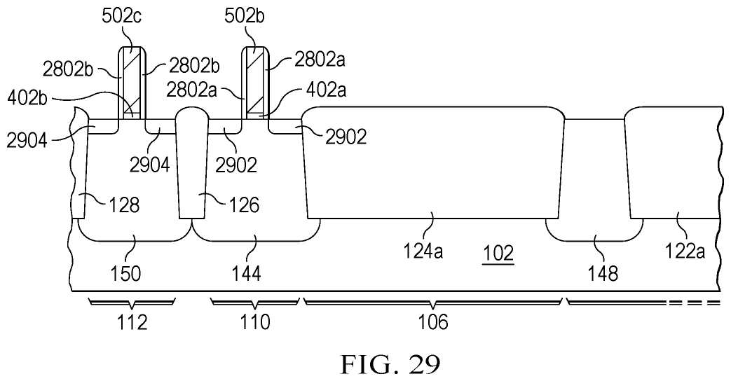

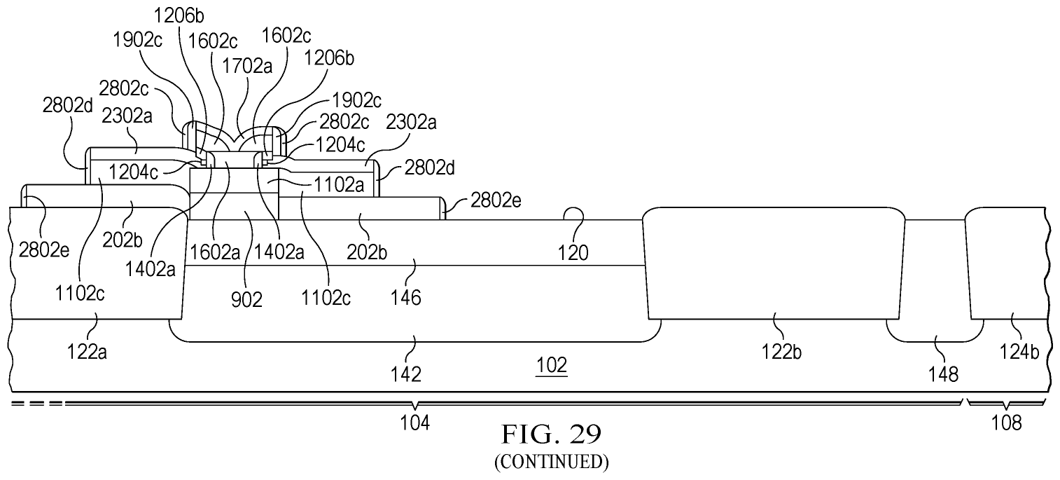

Referring to FIG. 29, p-type lightly doped drain regions (LDDs) 2902 and n-type LDDs 2904 are formed in the semiconductor substrate 102 in the pFET region 110 and the nFET region 112, respectively. The p-type LDDs 2902 are in the semiconductor substrate 102 on laterally opposing sides of the gate electrode 502b, and the n-type LDDs 2904 are in the semiconductor substrate 102 on laterally opposing sides of the gate electrode 502c. The p-type LDDs 2902 may be formed by masking (e.g., by a photoresist using photolithography) the BJT region 104, transition regions 106, 108, and nFET region 112 and implanting a p-type dopant into the semiconductor substrate 102 in the pFET region 110. The n-type LDDs 2904 may be formed by masking (e.g., by a photoresist using photolithography) the BJT region 104, transition regions 106, 108, and pFET region 110 and implanting an n-type dopant into the semiconductor substrate 102 in the nFET region 112. A concentration of the p-type dopant of the p-type LDDs 2902 is greater than the concentration of the n-type dopant of the n-type doped well 144, and a concentration of the n-type dopant of the n-type LDDs 2904 is greater than the concentration of the p-type dopant of the p-type doped well 150. In some examples, the p-type LDDs 2902 are doped with a p-type dopant with a concentration in a range from 1×10¹⁹ cm⁻³ to 1×10²¹ cm⁻³, and the n-type LDDs 2904 are doped with an n-type dopant with a concentration in a range from 1×10¹⁹ cm⁻³ to 1×10²¹ cm⁻³. Other doping concentrations may be implemented.

After performing implantation(s) to form the p-type LDDs 2902 and the n-type LDDs 2904, an activation anneal may be performed. In some examples with a lower thermal budget, the activation anneal includes a laser anneal following the first implantation (e.g., of n-type or p-type dopants) and a spike anneal reaching 930° C. or less following the second implantation (e.g., of the other of the n-type or p-type dopants).

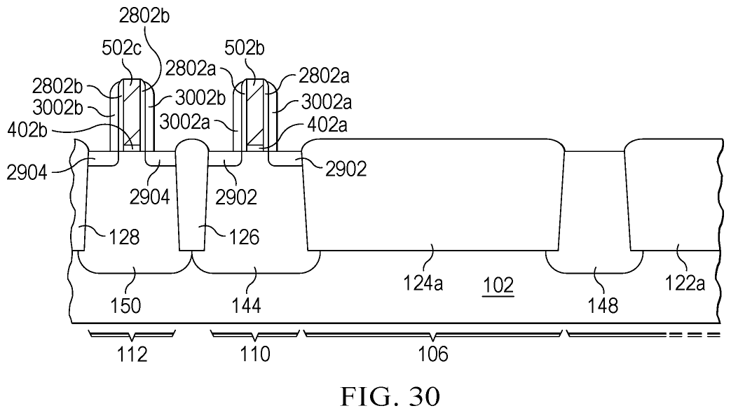

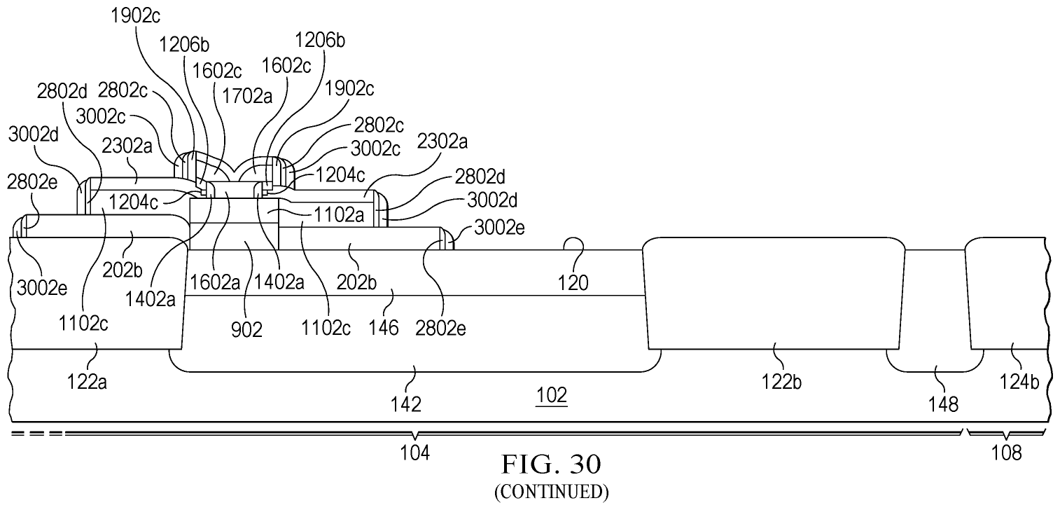

Referring to FIG. 30, second gate dielectric spacers 3002a, 3002b are formed along sidewalls of the first gate dielectric spacers 2802a, 2802b. The second gate dielectric spacers 3002a, 3002b may be formed by depositing a layer of the material of the second gate dielectric spacers 3002a, 3002b conformally over the semiconductor substrate 102 and anisotropically etching the layer such that the second gate dielectric spacers 3002a, 3002b remain. The material of the second gate dielectric spacers 3002a, 3002b may be any appropriate dielectric material, such as silicon nitride, silicon oxynitride, silicon carbon nitride, the like, or a combination thereof. The layer may be deposited by CVD, PECVD, ALD, or the like. The formation of the second gate dielectric spacers 3002a, 3002b may further form residual dielectric spacers 3002c. 3002d, 3002e on sidewalls of components in the BJT region 104. For example, residual dielectric spacers 3002c are on respective sidewalls of the residual dielectric spacers 2802c; residual dielectric spacers 3002d are formed on respective sidewalls of the residual dielectric spacers 2802d; and residual dielectric spacers 3002e are formed on respective sidewalls of the residual dielectric spacers 2802c.

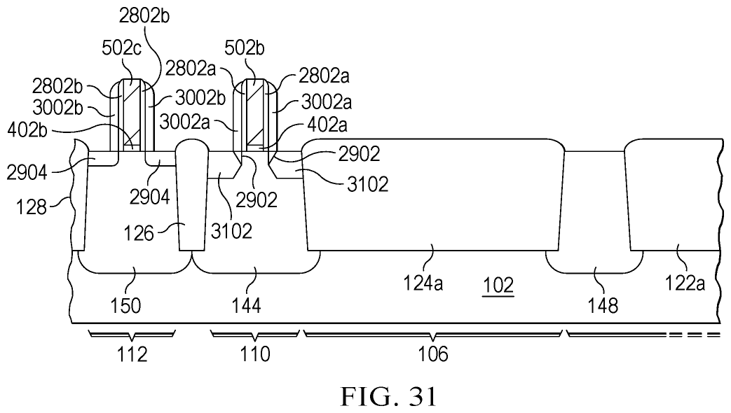

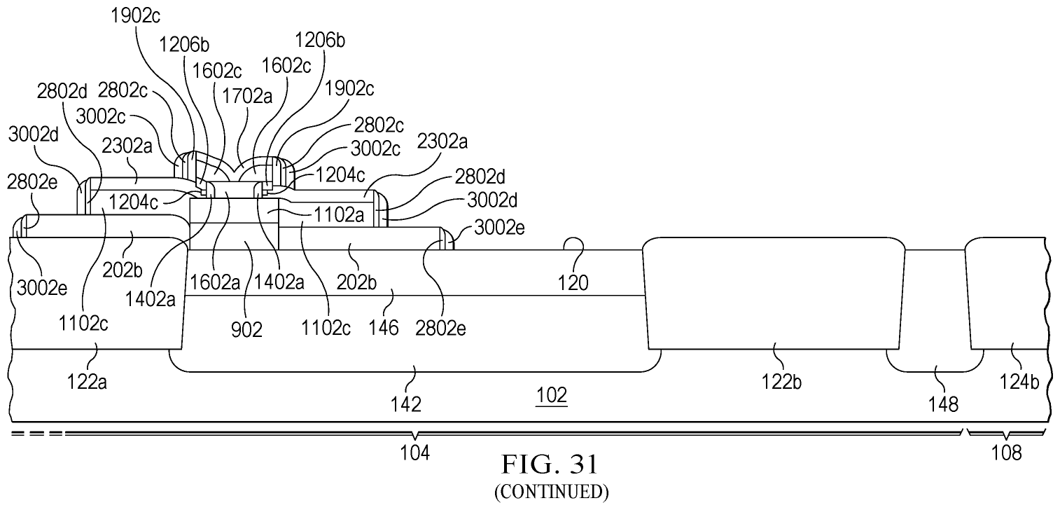

Referring to FIG. 31, embedded stressors 3102 are formed in the semiconductor substrate 102 in the pFET region 110. To form the embedded stressors 3102, respective recesses are formed in the semiconductor substrate 102. To form the recesses, a conformal hardmask layer is formed over the semiconductor substrate 102 in the BJT region 104, transition regions 106, 108, and nFET region 112. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching processes. Then, stressor recesses are formed in the semiconductor substrate 102 in the pFET region 110. The stressor recesses are etched in the semiconductor substrate 102 where the embedded stressors are to be formed. The stressor recesses may be formed using any appropriate etch process, which may be a wet or dry etch process. The etch process may be anisotropic and selective to (e.g., etching preferentially) a crystalline plane of the semiconductor substrate 102. The embedded stressors 3102 are then formed in the stressor recesses. The embedded stressors 3102 may be formed using a selective epitaxial growth process. The embedded stressors 3102 may be formed using MOCVD, molecular beam epitaxy (MBE), LPCVD, or another epitaxy process. After forming the embedded stressors 3102, the conformal hardmask layer is removed. The conformal hardmask layer may be removed by an etch process selective to the material of the conformal hardmask layer, which may be a wet or dry etch process.

A stress memorization technique may be implemented, such as in the nFET region 112. A stressor dielectric layer is formed over the semiconductor substrate 102, gate electrode 502c, and gate dielectric spacers 2802b, 3002b in the nFET region 112. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region 112. The anneal process may be or include a millisecond laser anneal for dopant activation and a spike rapid thermal anneal (RTA) with reduced thermal budget. A spike RTA may be at peak temperature for approximately 1 second and rapidly decrease in temperature to minimize dopant diffusion. The anneal process permits the lattice structure of the semiconductor substrate 102 to conform due to the stress induced by the stressor dielectric layer. After the anneal process, the stressor dielectric layer is removed. The stressor dielectric layer may be removed by an etch process selective to the material of the stressor dielectric layer, which may be a wet or dry etch process.

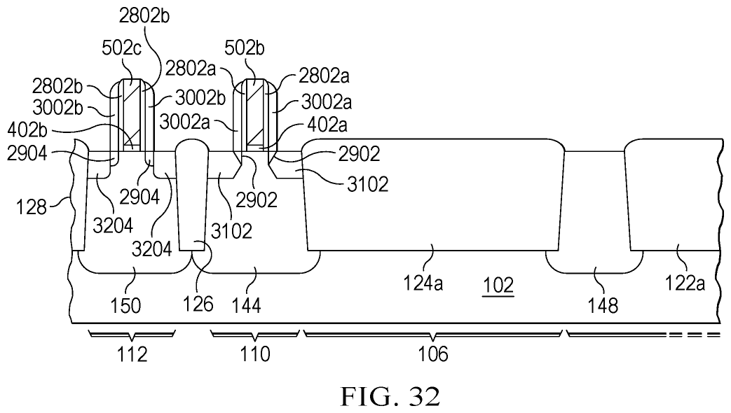

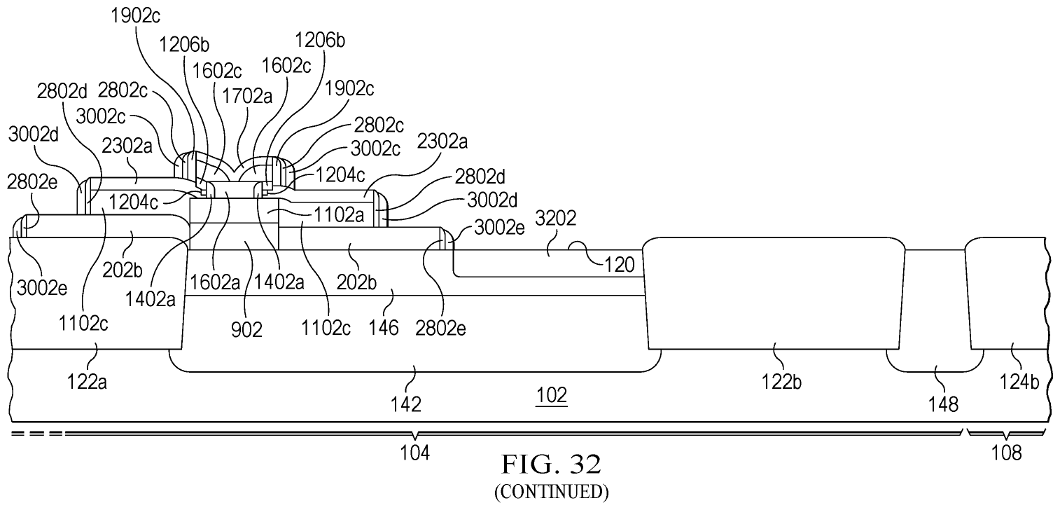

Referring to FIG. 32, an n-type collector contact region 3202, n-type source/drain (NSD) regions 3204, and p-type source/drain (PSD) regions are formed in the semiconductor substrate 102. The n-type collector contact region 3202 is formed in the BJT region 104 in the n-type doped sub-collector diffusion region 146 in the semiconductor substrate 102. The n-type collector contact region 3202 is laterally between the pedestal dielectric layer 202b and the second portion 122b of the isolation structure 122. The NSD regions 3204 are formed in the nFET region 112 in the p-type doped well 150 in the semiconductor substrate 102. The NSD regions 3204 are on opposing lateral sides of the gate electrode 502c with the n-type LDDs 2904 therebetween. The PSD regions are formed in the pFET region 110 and may be formed in the embedded stressors 3102 and/or may further extend below the embedded stressors 3102 into the n-type doped well 144 in the semiconductor substrate 102. The PSD regions are on opposing lateral sides of the gate electrode 502b with the p-type LDDs 2902 therebetween.

An implantation is performed to form the n-type collector contact region 3202 and the NSD regions 3204. The n-type collector contact region 3202 and the NSD regions 3204 may be formed by masking (e.g., by a photoresist using photolithography) the pFET region 110 and the base layer 1102, raised base layer 2302a, and emitter layer 1602 in the BJT region 104 and implanting an n-type dopant into the semiconductor substrate 102 in the nFET region 112 and exposed portion of the BJT region 104. An implantation is performed to form the PSD regions. The PSD regions may be formed by masking (e.g., by a photoresist using photolithography) the BJT region 104 and the nFET region 112 and implanting a p-type dopant into the semiconductor substrate 102 in the pFET region 110.

A concentration of the n-type dopant of the n-type collector contact region 3202 is greater than the concentration of the n-type dopant of the n-type doped sub-collector diffusion region 146. A concentration of the n-type dopant of the NSD regions 3204 is greater than the concentration of the n-type dopant of the n-type LDDs 2904 and the concentration of the p-type dopant of the p-type doped well 150. A concentration of the p-type dopant of the PSD regions is greater than the concentration of the p-type dopant of the p-type LDDs 2902 and the concentration of the n-type dopant of the n-type doped well 144. In some examples, the n-type collector contact region 3202 and the NSD regions 3204 are doped with an n-type dopant with a concentration in a range from 1×10²⁰ cm⁻³ to 1×10²¹ cm⁻³, and the PSD regions are doped with a p-type dopant with a concentration in a range from 1×10²⁰ cm⁻³ to 1×10²¹ cm⁻³. Other doping concentrations may be implemented.

After performing the implantations to form the n-type collector contact region 3202. NSD regions 3204, PSD regions, an activation anneal may be performed. In some examples with a lower thermal budget, the activation anneal includes a laser anneal following the first implantation (e.g., of n-type or p-type dopants) and a spike anneal reaching 1,010° C. or less following the second implantation (e.g., of the other of the n-type or p-type dopants).

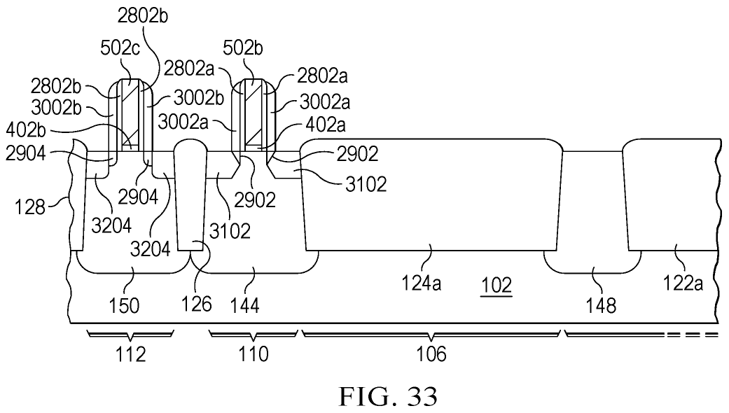

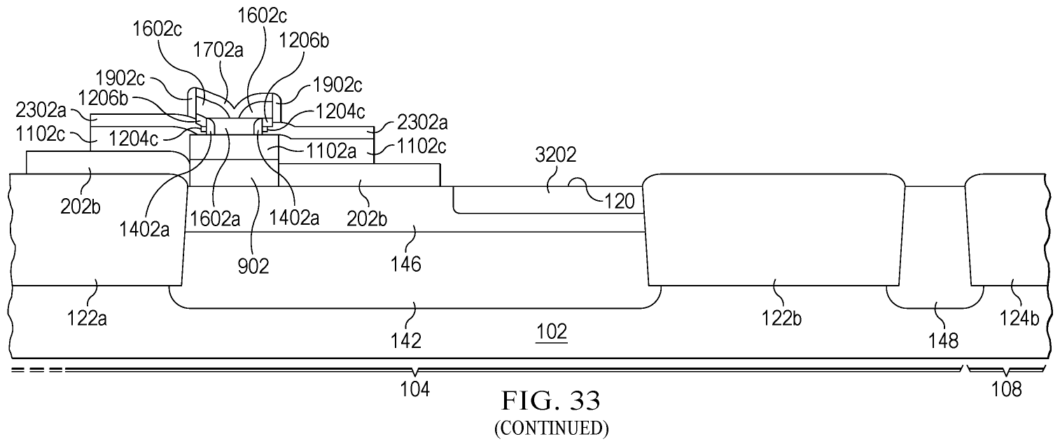

Referring to FIG. 33, residual dielectric spacers 2802c-2802e, 3002c-3002e may be removed. The residual dielectric spacers 2802c-2802e, 3002c-3002e may be removed by masking (e.g., by a photoresist using photolithography) the pFET region 110 and the nFET region 112 and performing an etch selective to the residual dielectric spacers 2802c-2802e, 3002c-3002e, which may be a wet or dry etch process.

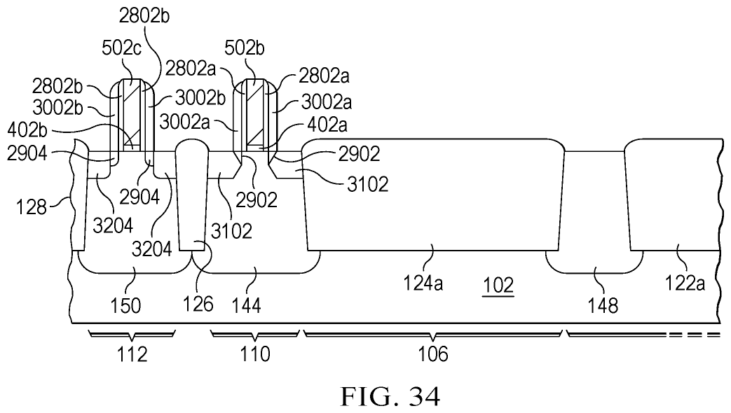

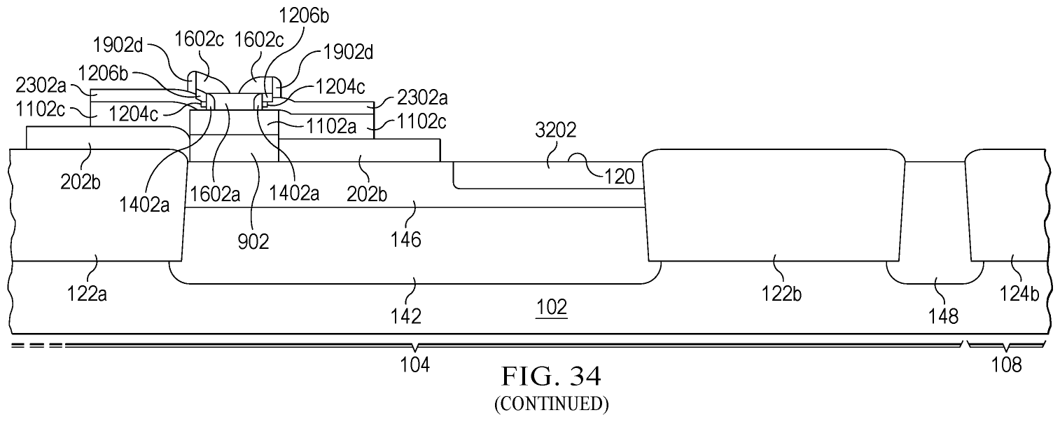

Referring to FIG. 34, the emitter dielectric cap layer 1702a is removed. The emitter dielectric cap layer 1702a may be removed by masking (e.g., by a photoresist using photolithography) remaining portions of the BJT region 104 and the transition regions 106, 108, pFET region 110, and nFET region 112 and performing an etch selective to the emitter dielectric cap layer 1702a. In some examples where the emitter dielectric cap layer 1702 and the emitter dielectric protective spacers 1902c are a same material, the removal of the emitter dielectric cap layer 1702a may also etch the emitter dielectric protective spacers 1902c to form emitter dielectric protective spacers 1902d.

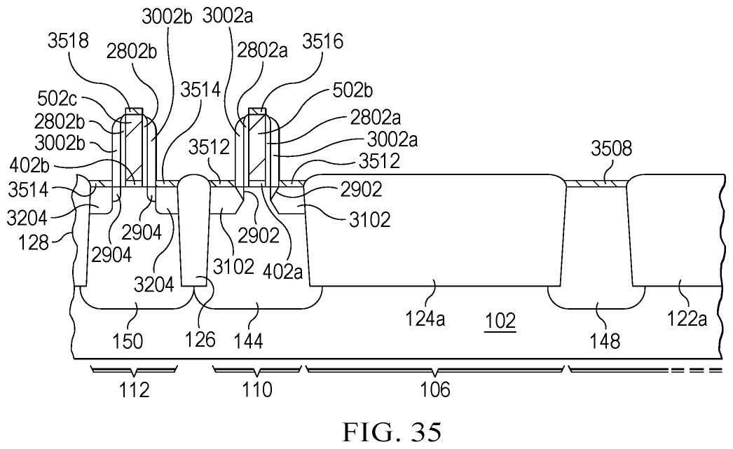

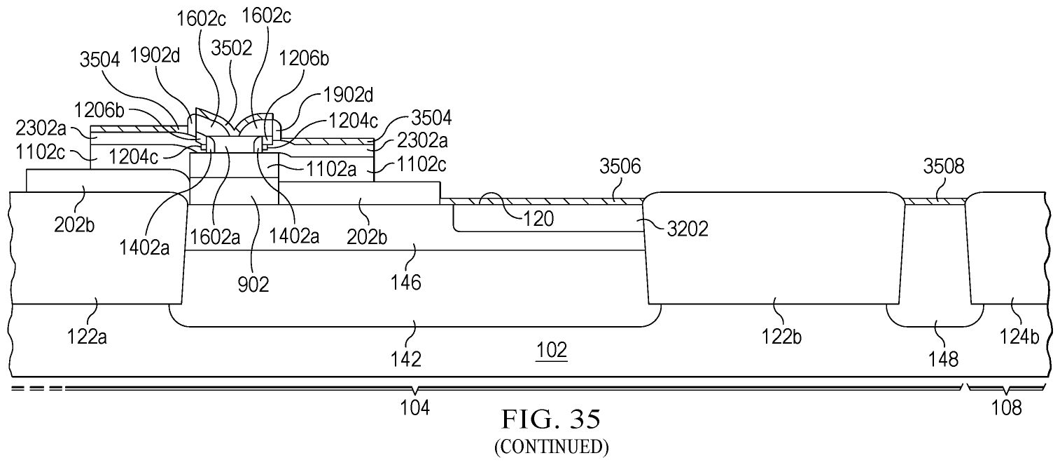

Referring to FIG. 35, metal-semiconductor compound 3502, 3504, 3506, 3508, 3512, 3514, 3516, 3518 are formed. The metal-semiconductor compound 3502 is on the emitter layer 1602 (e.g., the polycrystalline emitter layer 1602c and/or monocrystalline emitter layer 1602a). The metal-semiconductor compound 3504 is on the raised base layer 2302a. The metal-semiconductor compound 3506 is on the upper surface 120 of the semiconductor substrate 102 at the n-type collector contact region 3202. The metal-semiconductor compound 3508 is on the upper surface 120 of the semiconductor substrate 102 at the p-type doped well 148. The metal-semiconductor compound 3512 are on the embedded stressors 3102. The metal-semiconductor compound 3514 are on the NSD regions 3204 in the semiconductor substrate 102. The metal-semiconductor compound 3516, 3518 are on the gate electrodes 502b, 502c, respectively. The metal-semiconductor compound 3502, 3504, 3506, 3508, 3512, 3514, 3516, 3518 may be a silicide (e.g., NiSix, TiSix, CoSix, PtSix), a germanicide, or the like.

The metal-semiconductor compound 3502, 3504, 3506, 3508, 3512, 3514, 3516, 3518 may be formed by depositing a metal (e.g., Ni, Ti, Co. Pt) over the semiconductor substrate 102, such as by physical vapor deposition (PVD), CVD, or the like. The metal is reacted with a semiconductor material, such as the semiconductor material of the emitter layer 1602 (e.g., polycrystalline emitter layer 1602c and/or monocrystalline emitter layer 1602a), the semiconductor material of the raised base layer 2302a, the semiconductor material of the semiconductor substrate 102, the semiconductor material of the embedded stressors 3102, and the semiconductor material (e.g., silicon, such as polysilicon) of the gate electrodes 502b, 502c. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

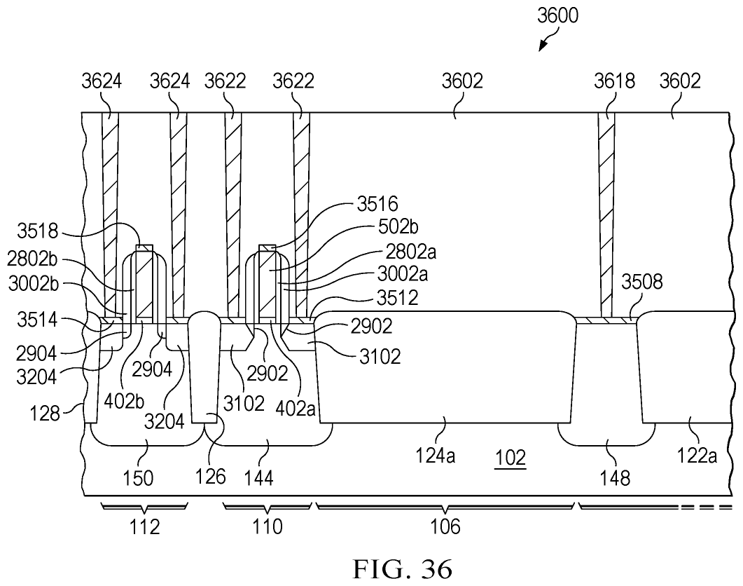

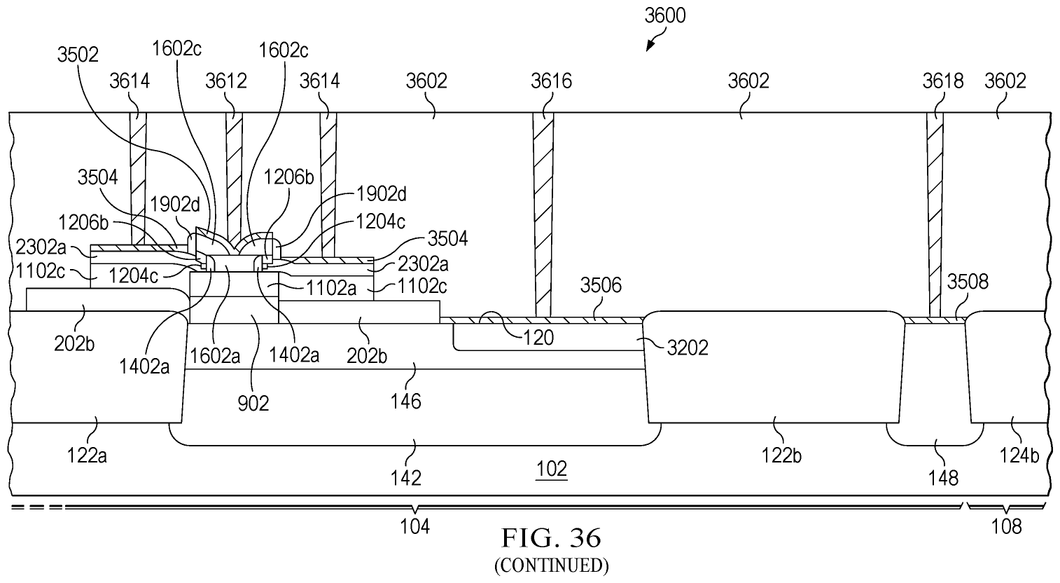

Referring to FIG. 36, a dielectric layer 3602 is formed over the semiconductor substrate 102, and contacts 3612, 3614, 3616, 3618, 3622, 3624 are formed through the dielectric layer 3602. The dielectric layer 3602 may include one or more dielectric sub-layers. For example, the dielectric layer 3602 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 3602 may be or include a pre-metal dielectric (PMD), an inter-layer dielectric (ILD), or the like. The dielectric layer 3602 may be deposited using CVD, PECVD, ALD, or the like. The dielectric layer 3602 may be planarized, such as by a CMP.

The contacts 3612, 3614, 3616, 3618, 3622, 3624 extend through the dielectric layer 3602 and contact respective metal-semiconductor compound 3502, 3504, 3506, 3508, 3512, 3514. The contacts 3612, 3614, 3616, 3618, 3622, 3624 may each include one or more barrier and/or adhesion layers (e.g., titanium nitride (TiN), tantalum nitride (TaN), the like, or a combination thereof) conformally in a respective opening through the dielectric layer 3602, and a fill metal (e.g., tungsten (W), copper (Cu), aluminum (Al), the like, or a combination thereof) over and/or on the barrier and/or adhesion layer(s).

To form the contacts 3612, 3614, 3616, 3618, 3622, 3624, respective openings may be formed through the dielectric layer 3602 to the metal-semiconductor compound 3502, 3504, 3506, 3508, 3512, 3514 using appropriate photolithography and etching processes. A metal(s) of the contacts 3612, 3614, 3616, 3618, 3622, 3624 are deposited in the openings through the dielectric layer 3602. The metal(s) may be deposited using an appropriate deposition process(es), such as CVD, PVD, or the like. Any excess metal(s) may be removed, such as by a CMP and/or by patterning using photolithography and etch processes.

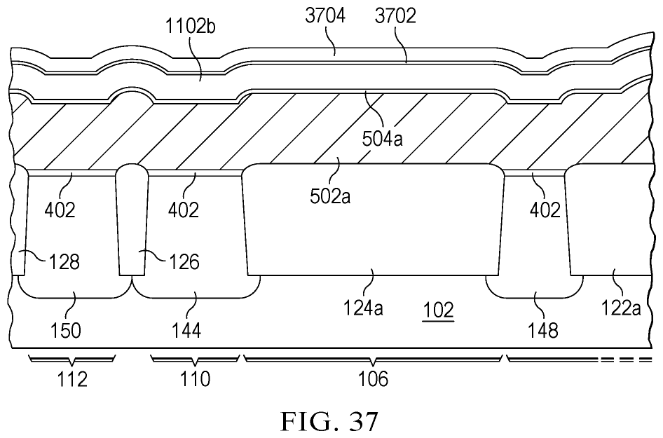

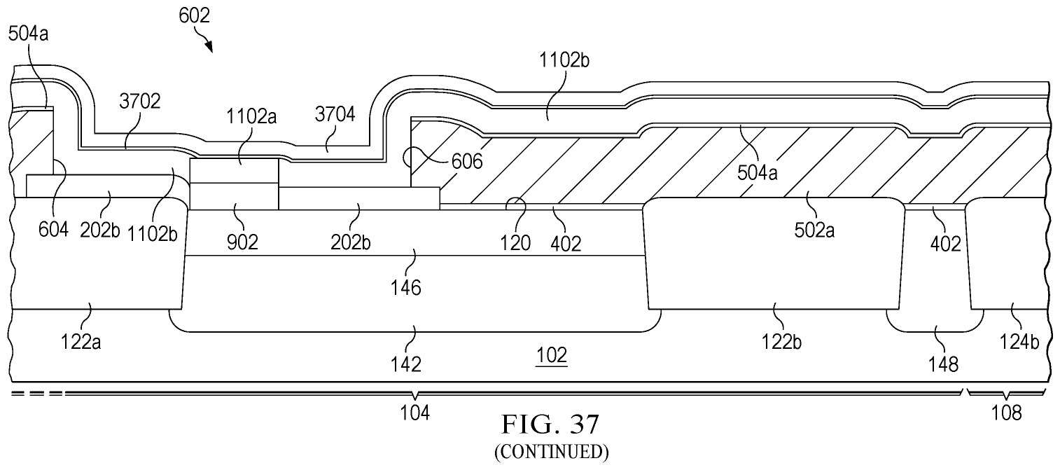

FIGS. 37 through 43 are respective cross-sectional views of a semiconductor device in intermediate stages of manufacturing according to some examples. Semiconductor processing proceeds as described above through FIG. 11.

With reference to FIG. 37, a first dielectric spacer layer 3702 is formed conformally over the base layer 1102, and a second dielectric spacer layer 3704 is formed conformally over the first dielectric spacer layer 3702. In some examples, the second dielectric spacer layer 3704 is a dielectric material different from the dielectric material of the first dielectric spacer layer 3702. In some examples, the first dielectric spacer layer 3702 is silicon oxide (e.g., a TEOS oxide), and the second dielectric spacer layer 3704 is silicon nitride. The dielectric spacer layers 3702, 3704 may be deposited by CVD. Other dielectric materials and/or other deposition processes may be used in other examples.

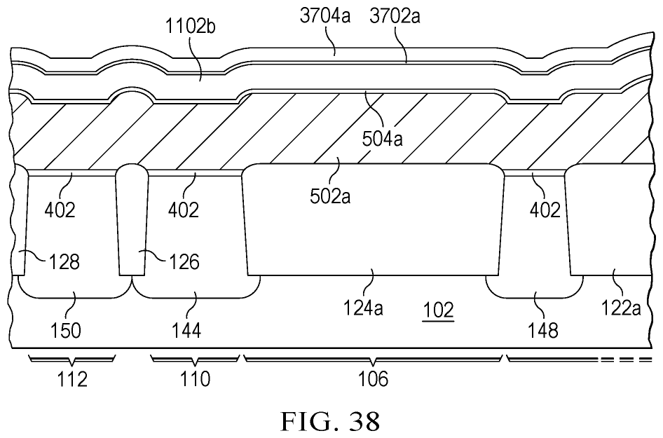

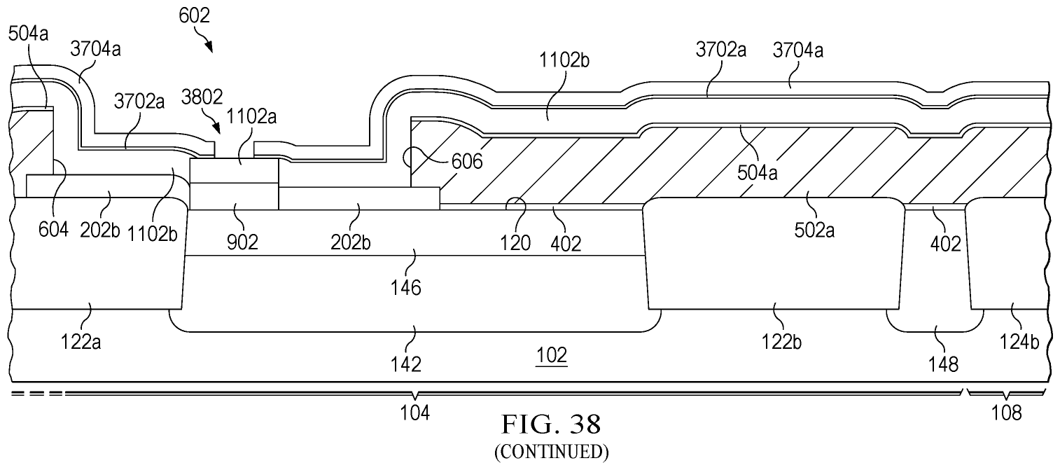

Referring to FIG. 38, the dielectric spacer layers 3702, 3704 are etched to form an emitter opening 3802 through the first dielectric spacer layer 3702a, and the second dielectric spacer layer 3704a. The dielectric spacer layers 3702, 3704 are etched through the opening 602 to form the emitter opening 3802. The monocrystalline base layer 1102a (of the base layer 1102) is exposed through the emitter opening 3802. The emitter opening 3802 is in the BJT region 104. The dielectric spacer layers 3702, 3704 may be etched using appropriate photolithography and etching processes. For example, an anisotropic etch, such as an RIE, may be implemented.

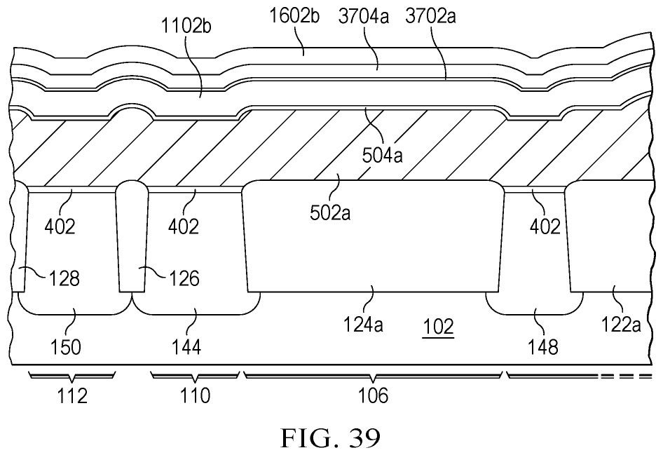

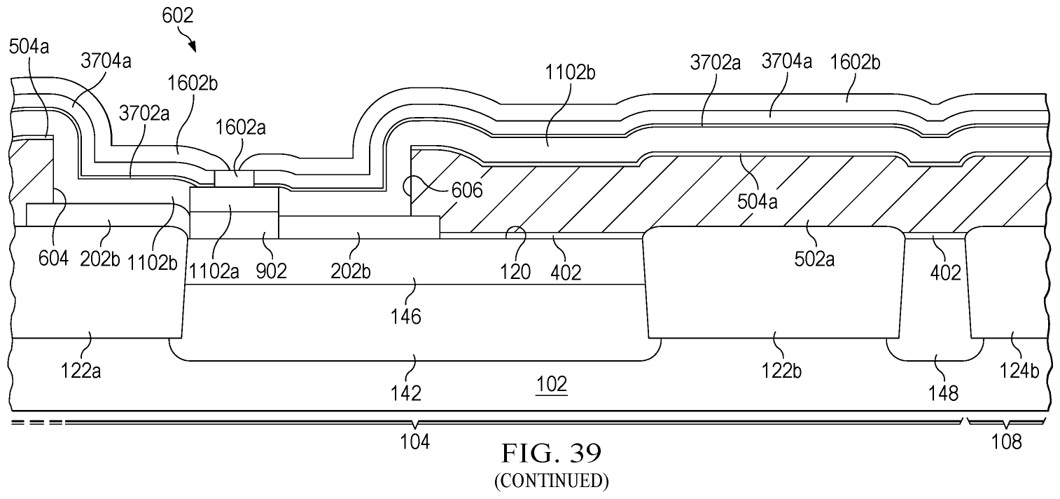

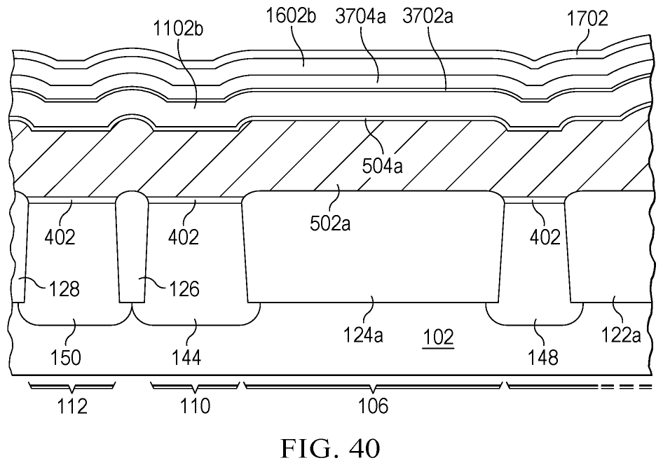

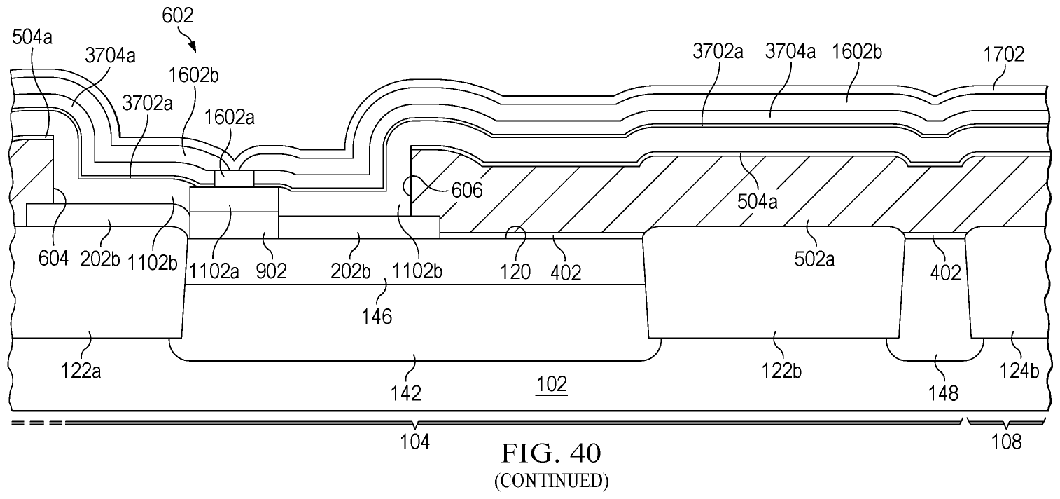

Referring to FIG. 39, an emitter layer 1602 is formed over the base layer 1102 (e.g., on the monocrystalline base layer 1102a) like described with respect to FIG. 16. The emitter layer 1602 may be epitaxially grown on the base layer 1102 (e.g., the monocrystalline base layer 1102a) exposed through the emitter opening 3802 and the second dielectric spacer layer 3704a. Referring to FIG. 40, an emitter dielectric cap layer 1702 is conformally formed over the emitter layer 1602 like described with respect to FIG. 17.

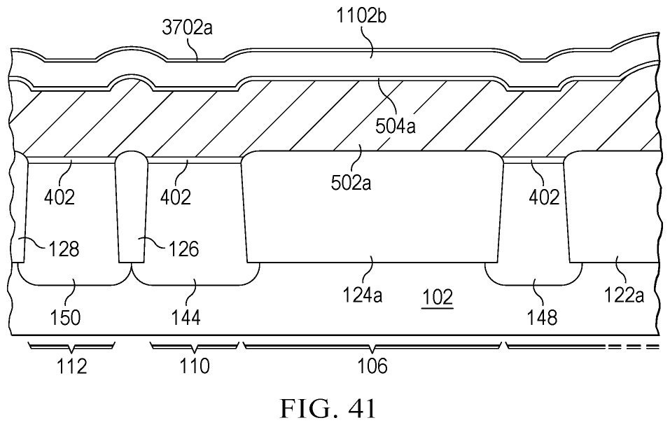

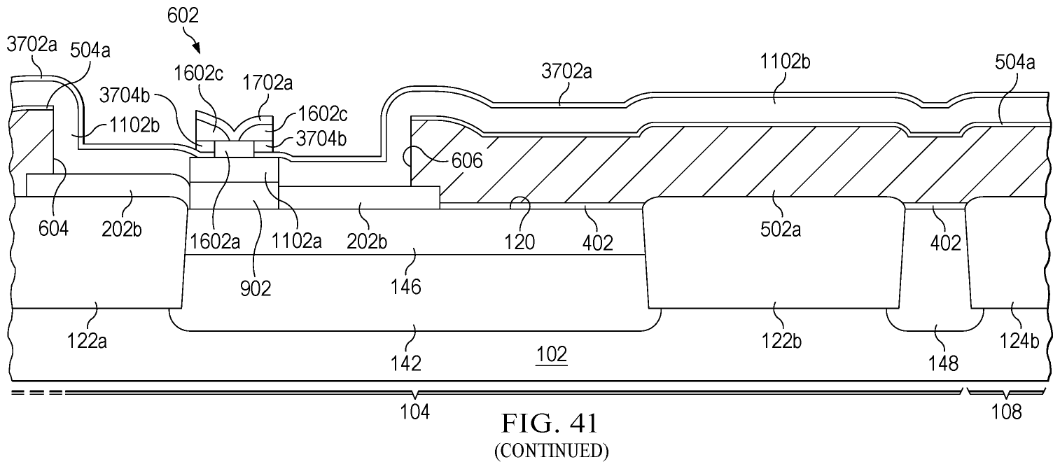

Referring to FIG. 41, the emitter dielectric cap layer 1702, polycrystalline emitter layer 1602b, and second dielectric spacer layer 3704a are etched to form the emitter dielectric cap layer 1702a, polycrystalline emitter layer 1602c, and second dielectric spacer 3704b in the opening 602. The layers 1702, 1602b, 3704a may be etched using appropriate photolithography and etching processes. For example, an anisotropic etch, such as an RIE, may be implemented.

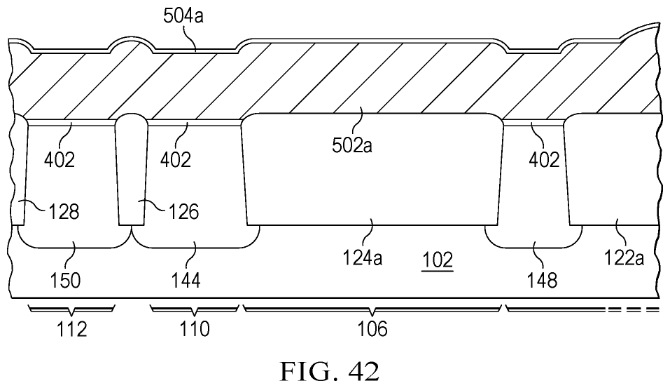

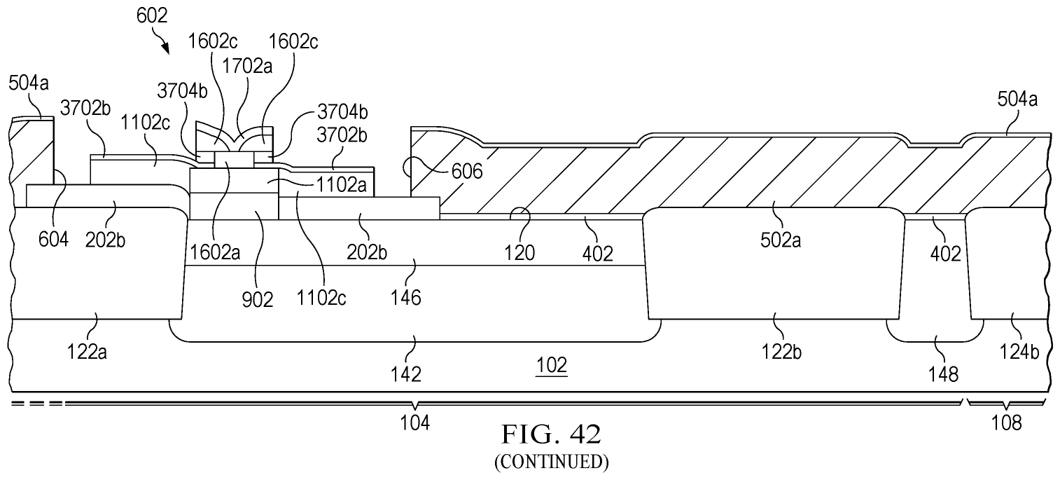

Referring to FIG. 42, the first dielectric spacer layer 3702a and the base layer 1102 (e.g., the polycrystalline base layer 1102b) are patterned. The polycrystalline base layer 1102b is patterned to remain as the polycrystalline base layer 1102c within the opening 602. Similarly, the first dielectric spacer layer 3702a is patterned to remain as the first dielectric spacer layer 3702b within the opening 602. The first dielectric spacer layer 3702a and the base layer 1102 outside of the opening 602, and more specifically, outside of the BJT region 104, are removed by the patterning. Hence, the base layer 1102 is removed from the sidewalls 604, 606 of the gate layer 502a and from over the dielectric protective layer 504a. The pedestal dielectric layer 202b extends laterally from the polycrystalline base layer 1102c over the first portion 122a of the isolation structure 122 in the BJT region 104 and extends laterally from the polycrystalline base layer 1102c over the upper surface 120 of the semiconductor substrate 102 in the BJT region 104. The first dielectric spacer layer 3702a and base layer 1102 may be patterned using appropriate photolithography and etching processes. For example, an anisotropic etch, such as an RIE, may be implemented.

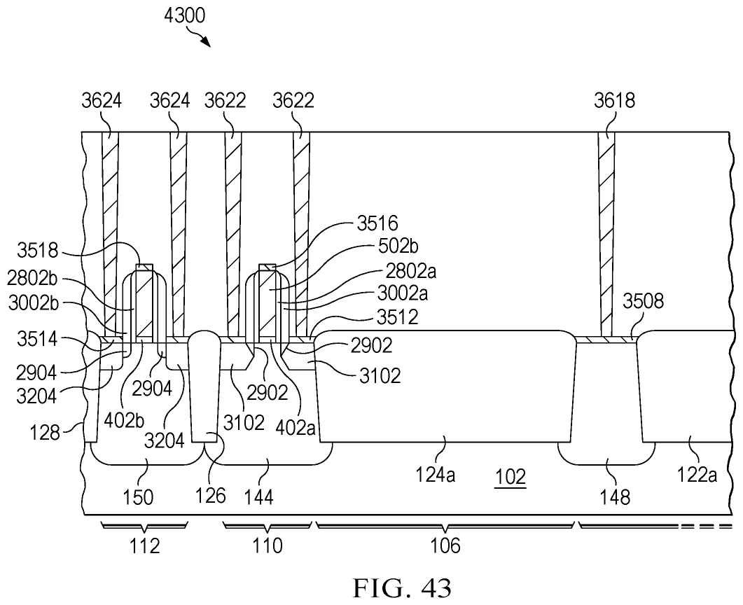

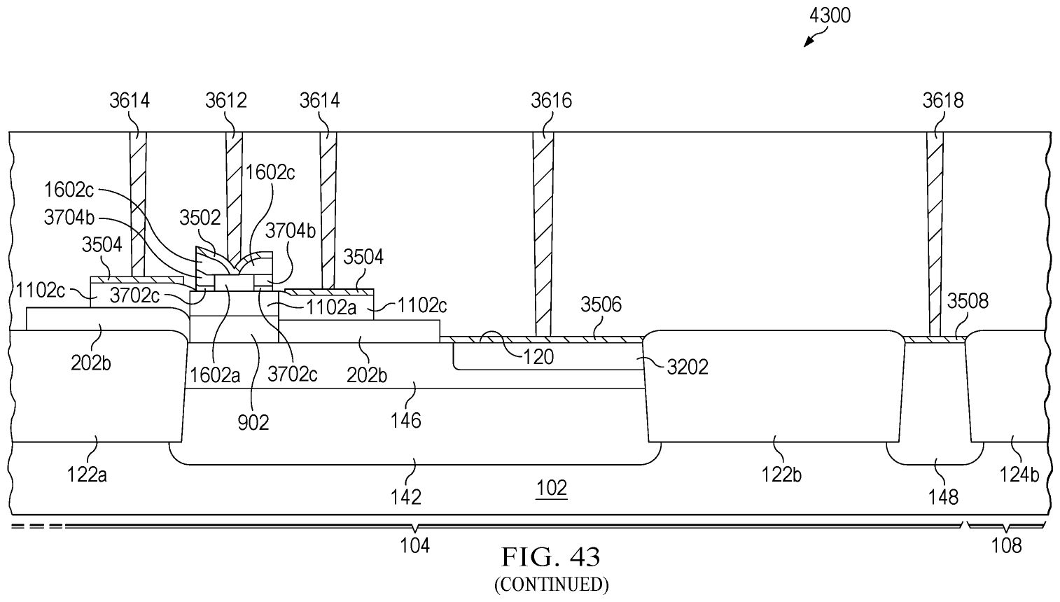

Referring to FIG. 43, semiconductor processing continues as described with respect to FIGS. 26 through 36 above. With respect to the formation of metal-semiconductor compound described above with respect to FIG. 35, metal-semiconductor compound 3504 is on the base layer 1102 (e.g., the polycrystalline base layer 1102c). The deposited metal is reacted with the semiconductor material of the base layer 1102 (e.g., the polycrystalline base layer 1102c).

FIGS. 36 and 43 illustrate respective semiconductor devices 3600, 4300. Each illustrated semiconductor device 3600, 4300 includes a BJT in the BJT region 104. The BJT includes the collector layer 902, base layer 1102 (e.g., monocrystalline base layer 1102a and polycrystalline base layer 1102c), and emitter layer 1602 (e.g., monocrystalline emitter layer 1602a and polycrystalline emitter layer 1602b). The BJT of the semiconductor device 3600 of FIG. 36 also includes a raised base layer 2302a on the base layer 1102 (e.g., on the polycrystalline base layer 1102c).

The collector layer 902 is over and on the upper surface 120 of the semiconductor substrate 102 and is through an opening in a pedestal dielectric layer 202b, which is also over and on the upper surface of the semiconductor substrate 102. The collector layer 902 is on the n-type doped sub-collector diffusion region 146 in the semiconductor substrate 102. The base layer 1102 (e.g., the monocrystalline base layer 1102a) is over and on the collector layer 902, and the base layer 1102 (e.g., the polycrystalline base layer 1102c) is over and on an upper surface of the pedestal dielectric layer 202b. The pedestal dielectric layer 202b extends laterally from the base layer 1102, such as laterally over and along the upper surface 120 of the semiconductor substrate 102 in a lateral direction from the base layer 1102 towards the n-type collector contact region 3202 and laterally along the first portion 122a of the isolation structure 122.

The emitter layer 1602 (e.g., the monocrystalline emitter layer 1602a) is over and on the base layer 1102 (e.g., the monocrystalline base layer 1102a) and is through an opening defined by a spacer structure, and the emitter layer 1602 (e.g., the polycrystalline emitter layer 1602c) is over and on the spacer structure. In the semiconductor device 3600 of FIG. 36, the spacer structure includes the second dielectric spacer 1204c, the third dielectric spacer 1206b, and emitter dielectric spacer 1402a. In the semiconductor device 4300 of FIG. 43, the spacer structure includes the first dielectric spacer 3702c and the second dielectric spacer 3704b.

The metal-semiconductor compound 3502 is on the emitter layer 1602 (e.g., the polycrystalline emitter layer 1602c and/or monocrystalline emitter layer 1602a). The metal-semiconductor compound 3506 is on the upper surface 120 of the semiconductor substrate 102 on the n-type collector contact region 3202. In the semiconductor device 3600 of FIG. 36, the metal-semiconductor compound 3504 is on the raised base layer 2302a. In the semiconductor device 4300 of FIG. 43, the metal-semiconductor compound 3504 is on the base layer 1102 (e.g., the polycrystalline base layer 1102c).

In some examples, the BJT may be a heterojunction BJT. As indicated previously, in some examples, the collector layer 902 and the emitter layer 1602 may be silicon, and the base layer 1102 may include silicon germanium. Hence, in some examples, the base layer 1102 may include a semiconductor material dissimilar from respective semiconductor materials of the collector layer 902 and emitter layer 1602. The dissimilar semiconductor materials may form one or more heterojunctions in the BJT, and the BJT may therefore be a heterojunction BJT.

Each illustrated semiconductor device 3600, 4300 includes a pFET in the pFET region 110 and an nFET in the nFET region 112. The pFET region 110 and nFET region 112 are in a CFET region. The pFET includes the gate electrode 502b, gate dielectric layer 402a, embedded stressors 3102, PSD regions, p-type LDDs 2902, and a channel region in the semiconductor substrate 102 underlying the gate electrode 502b. The gate electrode 502b is over and on the gate dielectric layer 402a, and the gate dielectric layer 402a is over and on the upper surface 120 of the semiconductor substrate 102. The p-type LDDs 2902 are on laterally opposing sides of the gate electrode 502b and in the semiconductor substrate 102. The channel region is laterally between the p-type LDDs 2902. The embedded stressors 3102 and PSD regions are on laterally opposing sides of the gate electrode 502b, with the p-type LDDs 2902 and channel region therebetween. Similarly, the nFET includes the gate electrode 502c, gate dielectric layer 402b, NSD regions 3204, n-type LDDs 2904, and a channel region in the semiconductor substrate 102 underlying the gate electrode 502c. The gate electrode 502c is over and on the gate dielectric layer 402b, and the gate dielectric layer 402b is over and on the upper surface 120 of the semiconductor substrate 102. The n-type LDDs 2904 are on laterally opposing sides of the gate electrode 502c and in the semiconductor substrate 102. The channel region is laterally between the n-type LDDs 2904. The NSD regions 3204 are on laterally opposing sides of the gate electrode 502c, with the n-type LDDs 2904 and channel region therebetween. The pFET and nFET may be complementary devices (e.g., complementary metal-oxide-semiconductor (CMOS) devices). In some examples, the pFET may be a p-type metal-oxide-semiconductor (PMOS) transistor, and the nFET may be an n-type metal-oxide-semiconductor (NMOS) transistor.

The first transition region 106 is between the BJT region 104 and the CFET region (e.g., with the CFET having a boundary of the pFET region 110 in the illustrated examples). As described with respect to FIG. 27, the gate layer 502a is patterned into the gate electrodes 502b, 502c such that the gate layer 502a is removed from the BJT region 104 and the first transition region 106. Hence, the BJT region 104 from the sidewall 304 of the pedestal dielectric layer 202b laterally through the first transition region 106 is exclusive of a material of the gate electrodes 502b, 502c of the pFET and nFET. Similarly, as described with respect to FIGS. 25 and 42, the base layer 1102 and (where appropriate) raised base layer 2302 are removed from the sidewall 304 of the pedestal dielectric layer 202b in the BJT region 104 laterally through the first transition region 106. Hence, the BJT region 104 from the sidewall 304 of the pedestal dielectric layer 202b laterally through the first transition region 106 is exclusive of respective materials of the base layer 1102 and raised base layer 2302.

The semiconductor processing to form the semiconductor devices 3600, 4300 of FIGS. 36 and 43 may enable vertical scaling and horizontal scaling. In some examples, for vertical scaling, thicknesses of the collector layer 902, base layer 1102, and emitter layer 1602 may be reduced. In some examples, a thickness of the collector layer 902 does not exceed 200 nm, and a thickness of the base layer 1102 (e.g., the monocrystalline base layer 1102a) does not exceed 100 nm. Further, in some examples, the thickness of the collector layer 902 is in a range from 10 nm to 100 nm, and a thickness of the base layer 1102 (e.g., the monocrystalline base layer 1102a) is in a range from 10 nm to 50 nm. Additionally, in some examples, a thickness of the emitter layer 1602 (e.g., the monocrystalline emitter layer 1602a) does not exceed 100 nm. In some examples, the thickness of the emitter layer 1602 (e.g., the monocrystalline emitter layer 1602a) is in a range from 10 nm to 50 nm. Generally, a thickness of a given layer is in a direction normal to a tangent plane of the underlying surface on which the given layer is formed. However, in some instances, such as with a conformal deposition, a direction normal to a tangent plane of the underlying surface may not be a thickness, such as where a thickness from another tangent plane intersects that direction normal, like at a corner.

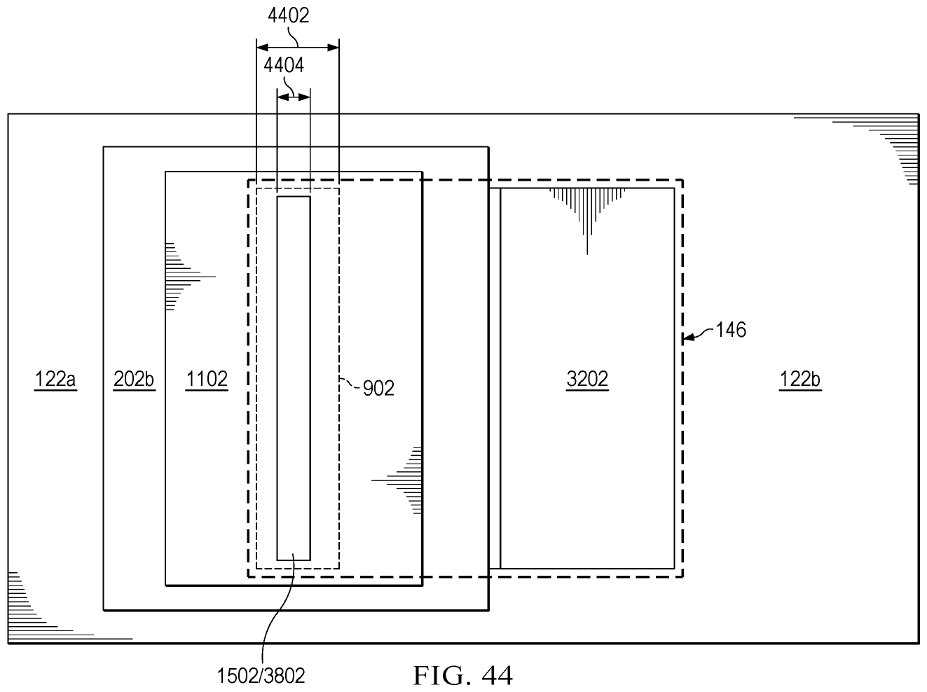

For horizontal scaling, widths of respective openings in which the collector layer 902 and the emitter layer 1602 (e.g., the monocrystalline emitter layer 1602a) are formed, may be reduced. The width of the collector opening 802, in which the collector layer 902 is formed, may be reduced, and the width of the emitter opening 1502, 3802, in which the monocrystalline emitter layer 1602a is formed, may be reduced. The semiconductor processing described above may enable horizontal scaling to, e.g., a 28 nm technology node and beyond (e.g., a 21 nm technology node or less). FIG. 44 depicts a layout of components that form the BJT in the semiconductor device 3600, 4300 of FIGS. 36 and 43. Among other things, FIG. 44 shows the lateral boundaries of the pedestal dielectric layer 202b. The collector layer 902 is shown laterally interior within the pedestal dielectric layer 202b, and the layout of the collector layer 902 corresponds to the collector opening 802 shown in FIG. 8. The collector layer 902 (and further, the collector opening 802) has a width 4402. The layout of the base layer 1102 (e.g., the polycrystalline base layer 1102c) is shown relative to the collector layer 902. The emitter opening 1502, 3802 shown in FIGS. 15 and 38 is shown relative to the base layer 1102 and the collector layer 902 and has a width 4404. The emitter layer 1602 (e.g., the monocrystalline emitter layer 1602a) is formed in the emitter opening 1502, 3802. One or both of the widths 4402, 4404 may be reduced for horizontal scaling. In some examples, the width 4402 does not exceed 200 nm, and the width 4404 does not exceed 120 nm. Further, in some examples, the width 4402 is in a range from 80 nm to 180 nm, and the width 4404 is in a range from 40 nm to 100 nm.

The BJTs in the semiconductor devices 3600, 4300 of FIGS. 36 and 43 may have improved characteristics relative to other BJTs. The BJTs in the semiconductor devices 3600, 4300 may have lower base resistance, lower collector resistance, and lower parasitic capacitance (e.g., including base-collector capacitance and collector-substrate capacitance). Further, the BJT of the semiconductor device 3600 of FIG. 36 may have even lower base resistance. The BJTs in the semiconductor devices 3600, 4300 of FIGS. 36 and 43 may further have higher operating frequencies. For example, in some examples, the BJT in the semiconductor device 3600 of FIG. 36 has a maximum frequency with unity current gain (ft_peak) of 608 GHZ, and the BJT in the semiconductor device 4300 of FIG. 43 has a ft_peak of 614 GHZ. Additionally, in some examples, the BJT in the semiconductor device 3600 of FIG. 36 has a frequency with a maximum power gain (fmax_peak) of 768 GHZ, and the BJT in the semiconductor device 4300 of FIG. 43 has a fmax_peak of 670 GHZ.

Semiconductor processing described above contributes to the improved characteristics. A shallow implant that forms a reduced width of the n-type doped sub-collector diffusion region 146 may contribute to a collector-substrate capacitance. A narrower active area of the semiconductor substrate 102 (e.g., between the portions 122a, 122b of the isolation structure 122) may reduce the base-collector capacitance, which may increase fmax_peak. Selective epitaxial growth of the collector layer 902 may decrease collector resistance, which may increase ft_peak. A high doping concentration of the raised base layer 2302a and selective epitaxial growth of the raised base layer 2302a may reduce the base resistance, which may further increase fmax_peak and lower noise figure of merit (NF). A thinner emitter layer 1602 may contribute to a reduced emitter resistance, which may further increase ft_peak and fmax_peak. However, a narrower width 4404 of the emitter layer 1602 may contribute to an increased emitter resistance, which may lead to decreased emitter-base capacitance and base resistance. A response of ft_peak to a narrower width 4404 of the emitter layer 1602 may depend on other process conditions. An impact of reduced base resistance may be large enough to increase fmax_peak when the emitter layer 1602 is narrower. In examples in which nickel (Ni) is used as the metal in the metal-semiconductor compound 3502, the emitter resistance may be reduced, which may further increase ft_peak. Further, implementing a lower thermal budget (such as by including laser anneal) may reduce dopant diffusion and increase dopant activation, which may reduce the base resistance and increase ft_peak and fmax_peak.

Although various examples have been described in detail, it should be understood that various changes, substitutions, and alterations can be made therein without departing from the scope defined by the appended claims.

What is claimed is:

1. A semiconductor device, comprising:
a semiconductor substrate including a bipolar junction transistor region;
a pedestal dielectric layer in the bipolar junction transistor region and over an upper surface of the semiconductor substrate;
a collector layer on the upper surface of the semiconductor substrate and through the pedestal dielectric layer;
a base layer on the collector layer and an upper surface of the pedestal dielectric layer, the pedestal dielectric layer extending laterally over the upper surface of the semiconductor substrate from the base layer; and
an emitter layer on the base layer.

2. The semiconductor device of claim 1, wherein the semiconductor substrate includes:
a doped sub-collector diffusion region, the collector layer being on the doped sub-collector diffusion region; and
a doped collector contact region in the doped sub-collector diffusion region, at least a portion of the pedestal dielectric layer being laterally between the collector layer and the doped collector contact region.

3. The semiconductor device of claim 1, wherein the base layer includes a material dissimilar from a material of the collector layer and a material of the emitter layer.

4. The semiconductor device of claim 3, wherein:
the material of the base layer includes silicon germanium;
the material of the collector layer is silicon; and
the material of the emitter layer is silicon.

5. The semiconductor device of claim 1, further comprising a raised base layer on the base layer.

6. The semiconductor device of claim 5, further comprising:
a base metal-semiconductor compound on the raised base layer; and
an emitter metal-semiconductor compound on the emitter layer.

7. The semiconductor device of claim 1, further comprising:
a base metal-semiconductor compound on the base layer; and
an emitter metal-semiconductor compound on the emitter layer.

8. The semiconductor device of claim 1, wherein:
the semiconductor substrate further includes a complementary field effect transistor (CFET) region;
the CFET region including a p-type field effect transistor (PFET) and an n-type field effect transistor (NFET); and
a region laterally between the CFET region and a sidewall of the pedestal dielectric layer is exclusive of a material of a gate electrode of the PFET or a gate electrode of the NFET above the upper surface of the semiconductor substrate.

9. The semiconductor device of claim 1, wherein:
a thickness of the collector layer does not exceed 200 nm; and
a thickness of the base layer does not exceed 100 nm.

10. The semiconductor device of claim 9, wherein:
the thickness of the collector layer is in a range from 10 nm to 100 nm; and
the thickness of the base layer is in a range from 10 nm to 50 nm.

11. A method, comprising:
forming a gate layer over a semiconductor substrate;
forming a first opening through the gate layer in a bipolar junction transistor (BJT) region;
forming a collector layer in the first opening and on an upper surface of the semiconductor substrate;
forming a base layer on the collector layer;
forming an emitter layer on the base layer; and
after forming the emitter layer, patterning the gate layer into a gate electrode of a transistor in a complementary field effect transistor (CFET) region of the semiconductor substrate.

12. The method of claim 11, wherein no portion of the gate layer remains in a region laterally between the CFET region and a sidewall of the collector layer after patterning the gate layer into the gate electrode of the transistor.

13. The method of claim 11, further comprising:
forming a pedestal dielectric layer over the upper surface of the semiconductor substrate, the first opening through the gate layer extending to the pedestal dielectric layer; and
forming, through the first opening, a second opening through the pedestal dielectric layer to the upper surface of the semiconductor substrate, the collector layer being formed in the second opening.

14. The method of claim 13, wherein the base layer is further formed on the pedestal dielectric layer.

15. The method of claim 11, further comprising, after forming the emitter layer, forming a raised base layer on the base layer.

16. The method of claim 15, further comprising reacting a metal with a semiconductor material of the raised base layer.

17. The method of claim 11, further comprising reacting a metal with a semiconductor material of the base layer.

18. The method of claim 11, wherein the base layer includes a material dissimilar from a material of the collector layer and a material of the emitter layer.

19. The method of claim 11, wherein:
a thickness of the collector layer does not exceed 200 nm; and
a thickness of the base layer does not exceed 100 nm.

20. A method, comprising:
forming a pedestal dielectric layer over a semiconductor substrate in a bipolar junction transistor region;
forming a gate layer over the semiconductor substrate and over the pedestal dielectric layer;
forming a first opening through the gate layer to the pedestal dielectric layer, wherein sidewalls of the gate layer defining the first opening are over the pedestal dielectric layer;
forming, through the first opening, a second opening through the pedestal dielectric layer to an upper surface of the semiconductor substrate;
forming, through the first opening, a collector layer in the second opening and on the upper surface of the semiconductor substrate;
forming, through the first opening, a base layer on the collector layer;
forming, through the first opening, an emitter layer on the base layer; and
patterning the gate layer into a first gate electrode of a p-type transistor and into a second gate electrode of an n-type transistor, the p-type transistor and the n-type transistor being in a complementary field effect transistor (CFET) region of the semiconductor substrate.
